(19) United States
(12) Patent Application Publication
(10) Pub. No.: US 2005/0184376 A1
(43) Pub. Date: Aug. 25, 2005

(54) System in package

(76) Inventor: Peter C. Salmon, Mountain View, CA (US)

Correspondence Address: Aldo J. Test;DORSEY & WHITNEY LLP, Suite 3400, 4 Embarcadero Center, San Francisco, CA, 94111, US

(21) Appl. No.: 10/783,163

(22) Filed: Feb. 19, 2004

(51) Int. Cl. H01L 23/02; H01L 21/44

(52) U.S. Cl. 257/686; 438/109; 257/692; 438/696; 257/778; 438/108

(57) ABSTRACT

A system in package (SIP) is fabricated on a sheet of copper foil. An interconnection circuit is fabricated on the foil using copper conductors and a dual damascene structure for each conductive layer. The preferred dielectric material is an amorphous fluorinated polymer called Cytop. Input/output traces of the interconnection circuit terminate in wells filled with solder. Chips are bumped and direct attached by inserting the bumps into the wells. The preferred bumps are gold stud bumps, and the preferred wells contain solder paste to a depth of approximately 15 microns. Imprinting is the preferred method for patterning; it enables 6-micron wide traces, 6-micron diameter vias, and a cost per well of around 0.02 cents. Stripline structures are described for a 4-layer stackup that can support operating frequencies of at least 10 GHz. New methods are proposed for testing the completed assembly and for rework of any chips that prove defective. After the assembly is fully tested and reworked in sheet form the copper foil is folded to form a stacked die package or system in package. 5-high and 9-high stacks are illustrated. The copper foil provides a low impedance thermal path for cooling every chip in the SIP.

### THE INVENTION

This invention relates to microelectronic assemblies, and more particularly to semiconductor chip assemblies in which several layers of chips are stacked in a single package.

### BACKGROUND OF THE INVENTION

A common approach to reducing cost and increasing performance of microelectronic systems is to provide higher levels of integration. This can be accomplished by creating more complex integrated circuit (IC) chips, or by integrating the chips more effectively into packages or onto system boards. For more effective integration of chips into packages, stacked die packages have been developed. However, existing stacked die packages and system in package (SIP) approaches have suffered from poor methods of testing the completed assembly and poor methods for replacing any die that prove defective. This has led to a relatively high cost of SIP solutions to date. In addition, current stacked die packages have poor thermal performance and this has limited the level of integration attainable. In particular, since most of the heat in current packages flows to the board on which the SIP is mounted, the top chips in a stack may get overheated.

Imprinting is a fabrication method for creating interconnection circuits whereby the circuit features are embossed rather than etched. Imprinting methods are used herein, coupled with chemical-mechanical polishing (CMP) for creating dual damascene copper circuits. Together, these methods are capable of creating traces with a thickness of 2 microns and a width of around 6 microns at a width tolerance of 0.5 microns. Vias can be formed between traces on any pair of layers, and the via diameter can be as small as 6 microns. This patterning precision enables striplines having controlled impedance to be built at a density 10-20 times greater than for conventional printed circuits fabricated using etched copper, drilled vias, and FR-4 epoxy-glass laminate. Furthermore, methods are introduced herein to overcome several problems that currently limit the technical capability of imprinted circuits. These problems include the inability to align more than two stacked layers with fine alignment accuracy such as ±2 microns layer to layer; and the inability to pattern multiple dielectric layers by hot embossing when all of the layers are comprised of the same material, softening at the same temperature. An optical alignment method is proposed to replace the conventional method of mechanically pinning the layers in a lamination stack. Heaters and sensors positioned adjacent the embossing surface are proposed for selectively heating only the topmost dielectric layer. An additional problem addressed herein is difficulty in separating the embossing tool from the imprinted substrate; this problem is addressed using the method of vapor-assisted release.

A new class of materials called fluorocarbon polymers has been developed for use as dielectrics in high frequency circuits. These can be crystalline such as polytetrafluoroethylene (PTFE) or amorphous such as Cytop. Cytop is manufactured by Asahi Glass Co. Ltd., in Tokyo, Japan, and is distributed by Bellex International, Del., USA. It has excellent dielectric properties at 10 GHz including a dielectric constant of 2.1 and a dissipation factor of 0.0007. It can be spun onto a wafer and cured using methods typical of other polymers such as polyimides. At 220° C. it has a low viscosity for imprinting and is the preferred dielectric material for most of the layers of the current invention.

The most popular method for flip chip attachment currently employs solder bumps on the chips mating with lands on the circuit board. A typical pitch is 200-250 microns between bump centers. Because the bump height varies, some bumps do not touch the corresponding lands and this can lead to poor solder connections. Also, the mechanical attachment is not strong enough to withstand shear forces arising from unmatched expansion/contraction in the materials as the temperature cycles during manufacture and operation; this leads to a requirement for an epoxy underlayer to strengthen the attachment. This underlayer makes rework of defective chips problematic because the underlayer can only be removed using a difficult procedure involving application of solvents and careful cleaning of the residues; fine trace terminations are typically damaged during this procedure. The current invention provides a flip chip attachment structure including a gold stud bump on the component side, mating with a well filled with solder on the board side (or vice versa). The solder paste in the well is typically 15 microns deep, providing a soft interface that can accommodate non-planarities. Existing equipment can fabricate gold stud bumps wherein the tips of the bumps are coplanar within ±3 microns over the area of a 200 mm semiconductor wafer. The pitch of these connections can be 100 microns or less. As will be explained, no epoxy underlayer is needed, and rework can be performed routinely, even at this fine pitch.

A current limitation on stacked die packages is that one face of the circuit must be presented to the board to provide an attachment site for electrically connecting between the stacked assembly and other electronic circuits. This restriction is removed in the current invention, because the required electrical connections can be alternatively provided by one or more high-density cables at any level in the stack, as will be further described.

The historical method for fabricating controlled impedance structures for signal traces (such as striplines) has been to alternate signal layers with power supply layers. Happy Holden has described an alternative method called Power Mesh Architecture. This architecture provides a practical way to make dense interconnection circuits for SIPs (including striplines) with only 4 patterned layers, as will be further described in the context of the current invention.

As previously mentioned, cooling limitations have restricted the application of stacked die packages. In the current invention, a common copper plane that is subsequently folded provides a direct heat sink opposite every chip in the assembly. The thickness of the copper plane can be varied according to the thermal demands of each SIP application, taking into account any height restrictions for the SIP. Vertical stacks with 5 planes and 9 planes are described herein; any number of planes can be provided in principle. Each plane can have chips on one or both sides. During manufacture, circuit carriers may be used to support thin copper foils. In addition, each completed SIP can be configured so that the topmost surface is a surface of the common copper heat sink material; this provides a simple and effective physical interface to external heat sinks, as will be further described. There are many degrees of freedom with a multi-level folded package; the order of the layers and the component population on each layer can be optimized for the particular packaging application.

The same fabrication process that is used to create the SIP can be used to create the system board to which the SIP is attached. In this case the system board will be fabricated on a copper substrate rather than the mainstream glass-epoxy material (FR-4). Following this approach, heat can be efficiently extracted at both the top and the bottom of the SIP stack. This is relevant to nearly all high-performance systems wherein the heat generated during operation is a limiting design factor.

The methods of the current invention can be applied to manufacturing substrates in multiple form factors, including wafers and flat panels. For brevity, the wafer approach is detailed, with exceptions noted for flat panels.

Early versions of stacked die packages used wire bonded connections between chips and between chips and package surfaces. The electrical performance of such wire bonded leads is typically inferior to the performance of direct chip attach (flip chip), because the wire bonded leads are longer and have higher inductance, capacitance, and resistance. The material cost is typically higher, and the ordering of input/output pads on the chips and package surfaces is highly constrained in order to provide space and clearance for each of the wire bonds; typically only one chip per vertical layer of the stacked package can be accommodated. The current invention uses flip chip assembly having higher density (fine pad pitch in an area array rather than just at the chip perimeter) and relatively few constraints on the pad ordering. Also, multiple chips can be easily assembled on each layer in the stack. Finally, because the flip chip terminals (bumps or wells) can be closely spaced (100 microns or less) in an area array, good power distribution can be implemented using short leads of low inductance by locating power devices close to their loads.

A de facto standard for the height of stacked die packages in some applications is 1.2 mm. Methods have been developed for reducing the thickness of IC chips to around 50 microns. If 1 oz copper foil with a thickness of 34 microns is employed as the substrate in SIPs of the current invention and bump/well connections are used for chip and board attachments, and all chips are thinned to 50 microns, then the current invention supports a 7-high stack single-sided and a 4-high stack double-sided, within the 1.2 mm height limit. Other SIP applications will require thicker copper to get the heat out, and those packages must be greater in height or the number of layers must be reduced, to stay within the 1.2 mm height specification.

### SUMMARY OF THE INVENTION

The current invention provides improvements in the following areas: higher levels of integration within a single SEP, an effective method for testing the completed assembly including a full speed functional test, effective replacement of defective die (rework), and effective cooling of the SIP. Collectively, these methods enable a system in package having high speed and high density with adequate cooling and low manufacturing cost.

The first half of this application addresses circuit topographies relating to stacked die packages and particular SIP implementations. Multi-layer circuits built on copper substrates are described; both interconnection layers and special assembly layers are included. Such multi-layer circuits can be used as substrates for SIPs, as well as for system boards to which the SIPs and/or other components are attached; both applications are covered by the current invention. Flip chip connections in the form of solder balls mated with corresponding lands are contrasted with gold stud bumps inserted into wells filled with solder. The bump/well connections are finer in pitch, lower in height, have lower inductance, are re-workable, and are less expensive per lead if the preferred manufacturing methods described herein are employed in their fabrication. Fine pitch cables and cable attachments using bumps and wells are also described and are part of the current invention. Some of the many ways of folding the assembly are illustrated, and the utility of using the copper substrate to create structures with good heat-sinking capabilities is also described.

The second half of this application addresses equipment and procedures for building the proposed SIP structures. The imprinting method is described along with CMP for patterning dual damascene copper structures, at the dimensions required for a dense circuit board. The proposed trace dimensions are approximately mid-way between current IC chip trace and FR-4 board trace dimensions. Modifications to the embossing equipment to support improved alignment of multiple layers as well as selective heating of the dielectric layers are described. A dense 4-layer structure for the interconnection circuit of the SIP is illustrated, and recommended dimensions for controlled impedance structures are presented. Both wafer and flat panel substrates are described, as well as carriers for use with thin substrates in both form factors. Alternative shapes for the SIP substrate are presented, including surfaces with multiple lobes and also surfaces arrayed linearly to form a strip of foldable surfaces.

### BRIEF DESCRIPTION OF THE DRAWINGS

Preferred embodiments of the invention are described below with reference to the following accompanying drawings:

FIG. 1 is a top view of a foldable circuit board of the current invention;

FIG. 2 shows a fragment of section AA of FIG. 1, revealing the circuit layers;

FIG. 3 is a cross-sectional view of a pair of solder bumps at the base of an SIP, section BB of FIG. 1;

FIG. 4 is a top view of an assembled SIP prior to folding;

FIG. 5 shows section CC of FIG. 4;

FIG. 6 is a cross-sectional view of a pair of bump/well connections;

FIG. 7 is a cross-sectional view of a 5-layer SIP of the current invention;

FIG. 8 is a cross-sectional view of a 5-layer SIP of the current invention wherein each layer is 2-sided and a cable connects between two middle layers;

FIG. 9 is a top view of a 5-layer SIP of the current invention wherein gold stud bumps at a finer pitch replace the solder ball terminals of FIG. 4;

FIG. 10 is a cross-sectional view like FIG. 7 except that the terminals of the SIP connecting to the board are fine-pitched stud bumps rather than solder balls;

FIG. 11 is a cross-sectional view like FIG. 10 except that the board is fabricated on a copper substrate rather than a conventional glass-epoxy laminate;

FIG. 12 is a top view of a foldable interconnection circuit having nine delineated planar surfaces;

FIG. 13 is a cross-sectional view of a folded 9-layer SIP of the current invention;

FIG. 14 illustrates in cross-section an integrated assembly including multiple SIPs of the current invention, with copper planes top and bottom for ruggedness and cooling;

FIG. 15(a)-(c) is a set of schematic cross-sectional views showing process steps for imprinting, as exemplified using a simple embossing machine;

FIG. 16 is a schematic cross-sectional view of an embossing machine that includes a vacuum chamber enclosing the tool and substrate;

FIG. 17(a) is a top view of an embossing tool fragment including a trench and a via;

FIG. 17(b) is a cross-sectional view of the embossing tool fragment of FIG. 17(a);

FIG. 17(c) is a cross-sectional view of an imprint made by the embossing tool fragment of FIG. 17(b);

FIG. 18(a)-(f) depicts in schematic cross-section a first sequence of steps for fabricating an embossing tool of the current invention;

FIG. 19(a)-(c) depicts in cross-section a second sequence of steps for fabricating an embossing tool of the current invention;

FIG. 19(d) shows an expanded view of a preferred alignment target arrangement;

FIGS. 20-22 show top views of an embossing tool of the current invention, following successive fabrication stages;

FIG. 20 depicts an embossing tool carrier with a power resistor patterned on top;

FIG. 21 depicts the embossing tool carrier of FIG. 20, including thermocouple elements patterned on top;

FIG. 22 depicts the embossing tool carrier of FIG. 21, including embossing features fabricated on top;

FIG. 23 is a schematic cross-sectional view of a preferred alignment stackup in an embossing machine of the current invention;

FIG. 24 is a top view of a copper wafer containing 4 SIP substrates of the current invention;

FIG. 25(a)-(c) illustrates in cross-section preferred substrate/carrier alternatives for SIPs of the current invention;

FIG. 26 is a top view of a layout of a large number of SIP substrates delineated on a copper panel of the current invention;

FIG. 27A is a cross-sectional view of a fragment of a high-density cable of the current invention, fabricated using two imprinted layers;

FIG. 27B is a cross-sectional view of a fragment of a high-density cable of the current invention, fabricated using four imprinted layers;

FIG. 28(a)-(f) illustrates in cross-section a summary of the processing steps for patterning a pair of layers of an SIP interconnection circuit of the current invention;

FIG. 29(a)-(e) illustrates in cross-section a summary of the additional processing steps for creating a special assembly layer on top of the interconnection circuit, to include terminals having wells filled with solder;

FIG. 30A is a top view of a foldable circuit board showing a preferred location for guard rails of the current invention;

FIG. 30B shows a top expanded X-ray view of a short length of the guard rail structure;

FIG. 31 is a cross-sectional view of an embossing tool in close proximity to the topmost layer of an SIP interconnection circuit in progress;

FIG. 32A is a cross-sectional view of an embossing tool as it selectively heats and imprints the topmost dielectric layer of an SIP interconnection circuit in progress;

FIG. 32B is a schematic depiction of vapor-assisted release of the embossing tool;

FIG. 33 illustrates a fragmentary cross-section of a preferred structure for an SIP of the current invention;

FIG. 34 is a cross-sectional view of a differential pair of signal traces formed as transmission lines having a characteristic impedance;

FIG. 35 is a cross-sectional view of single-sided transmission lines having a characteristic impedance;

FIG. 36 is a schematic top view showing typical escape routing at an attachment site of the current invention;

FIG. 37 is a top view layout of a foldable printed circuit board of the current invention, in strip form;

FIG. 38 is a cross-sectional view of an alternative stacked assembly of the current invention; and

FIG. 39 is a flow chart summarizing the primary process steps to create an SIP of the current invention.

### DETAILED DESCRIPTION OF THE PREFERRED EMBODIMENTS

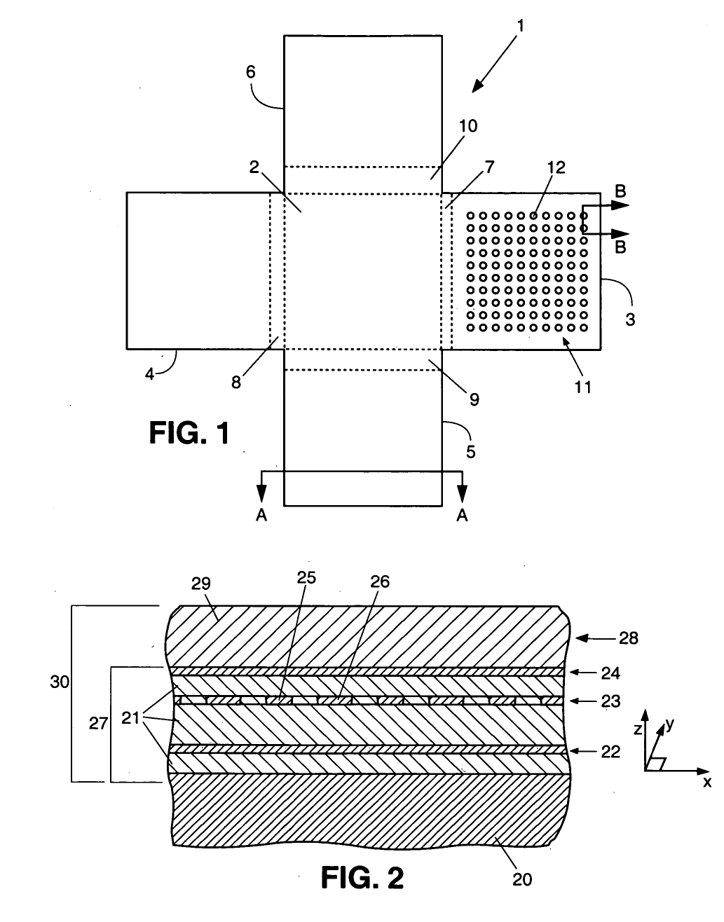

FIG. 1 is a top view of a foldable circuit board 1 of the current invention with five delineated surfaces including a center surface 2 and four tab-like surfaces 3-6 arranged around it. Rectangular areas 7-10 are reserved for hinges in the folded assembly. The first tab folded 3 will require a small hinge area 7 and the last tab folded 6 will require a larger hinge area 10 because the total thickness of the stacked layers (folded surfaces) increases with each additional folded surface. Tab surface 3 includes an array 11 of bump terminals 12 for connection to a printed circuit board, including provisions for signals and/or power. The array 11 of bumps 12 is one form of attachment site, in this case for attaching the SIP to a circuit board.

FIG. 2 illustrates a fragment of cross-section AA of FIG. 1, expanded to show a preferred layer structure. A substrate of conductive material 20, preferably copper or an alloy of copper supports multiple conductive and dielectric layers. Conductive substrate 20 will provide effective cooling paths in the finished assembly. It is a bendable foil or sheet, preferably connected to ground (GND) in the current invention. Dielectric layers 21 preferably employ a material having low dielectric constant and low dissipation factor at the operating frequency range of the integrated circuit (IC) chips to be mounted in the stacked die package. The preferred dielectric material 21 in the current invention is an amorphous fluorinated polymer called Cytop. At 10 GHz Cytop has a dielectric constant of 2.1 and a dissipation factor of 0.0007. Conductive layer 22 includes copper traces for both signals and power running in the x-direction; conductive layer 23 includes similar traces running in the y-direction. A signal trace 25 and a power trace 26 are shown. Signal traces may be implemented as transmission lines having controlled impedance for high frequency operation, as will be further described. Conductive layer 24 is preferably a ground layer with feedthroughs for signals and power, as will be further described. Collectively, layers 20-24 implement interconnection circuit 27. Atop interconnection circuit 27 is a special assembly layer 28, preferably comprised of a different dielectric material 29 such as polyimide that doesn't soften with increasing temperature, as does Cytop. As will be further explained, connection terminals in the form of wells filled with solder are preferably fabricated in layer 28. Since polyimide can typically tolerate temperatures of 350° C. it is a robust material for containing molten solder, especially the low temperature solder of the current invention, to be further described. The combined multi-layer circuit 30 includes interconnection circuit 27 and special assembly layer 28.

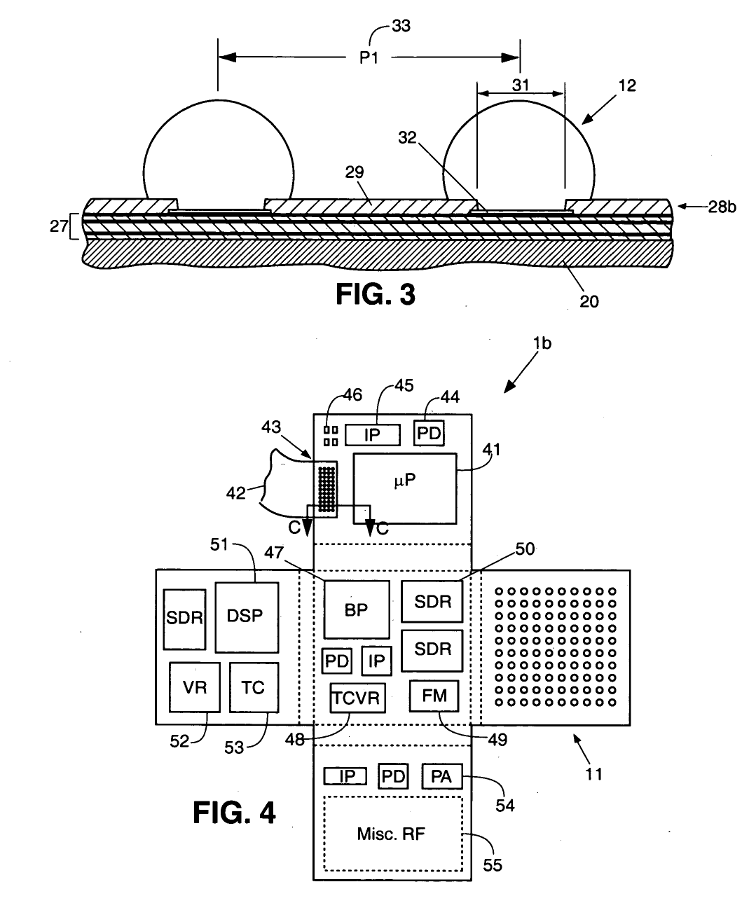

FIG. 3 is an expanded view of section BB of FIG. 1, showing a pair of solder ball terminals. A solder ball array may be used in SiPs of the current invention as an attachment site for connecting the SIPs to a circuit board; however a preferred approach is to use denser connections that also can be more effectively reworked, as will be further discussed. Conductive substrate 20 supports interconnection circuit 27 as previously described in reference to FIGS. 1 and 2. Special assembly layer 28b includes openings 31 in dielectric coating 29 and solder ball 12 of FIG. 1 is formed over the opening. Under bump metallization (UBM) 32 may be provided under solder ball 12 as is known in the art; it provides a solder-wettable and oxidation-resistant layer, and a barrier to diffusion of solder materials into interconnection circuit 27. A typical pitch (P1) 33 for terminals in a ball grid array like 11 is 200-250 microns. The height of the balls must be consistent, else air gaps between the bumps and corresponding lands on the circuit board to which the SIP is attached will lead to weak connections or open circuits; this is a known problem with current ball grid arrays.

FIG. 4 shows foldable printed circuit board 1 of FIG. 1 with attached components; it is now a circuit assembly and is labeled 1b. The attached components are examples of the kind of elements that may be employed in a portable wireless device. Included are a microprocessor chip 41, a high-density cable 42 with cable attachment site 43, a power distribution device 44, an integrated passives device 45, surface mounted components 46, baseband processor 47, transceiver 48, flash memory 49, synchronous dynamic RAM 50, digital signal processor 51, video RAM 52, test chip 53, power amplifier 54, and miscellaneous RF circuits and components 55. RF circuits 55 may be fabricated directly on dielectric 21 of FIG. 2 to implement passive devices like couplers and antennas; they may be interspersed with active devices like oscillators and mixers that are provided on chips. Note that power distribution (PD) devices 44 and integrated passive (IP) devices 45 are provided in multiple locations, to provide their functions as closely as possible to their points of use. Alternatively, one or more of the delineated surfaces may be intentionally bare of components, serving only as a heat transport layer.

To perform a high speed functional test of an SIP requires short leads between the system nodes inside the package and corresponding tester nodes inside the tester; then the dynamic behavior of the system under test can be captured and verified against a known good logic reference. The logic reference may be another known good system or it may consist of test vectors defined for each test cycle, wherein each test vector contains a series of bits and each bit represents the correct binary state of a digital signal at the instant of testing. It is possible to use the attachment site at the interface between the SIP and the board as a test port for performing such high-speed tests. Alternatively, a cable like 42 in FIG. 4 can be used as a high-speed connection to a tester. Another alternative is to provide one or more test chips such as 53 of FIG. 4 inside the SIP. Such a test chip may include high-speed sampling and comparator circuits that can be loaded with test files from a test support computer. One or other of these test methods is required for locating any defective components within the SIP. In the current invention, using a resident test chip is preferred, and all testing is completed and any defective parts replaced while SIP substrate 20 is in its planar form. After SIP substrate 20 has been folded to form a stack, the resident test chip can be used to monitor the health of the SIP, and report any deviations from correct system function. If a complex system has multiple SIPs, this health monitoring function may be employed to help locate any failures within the complex system.

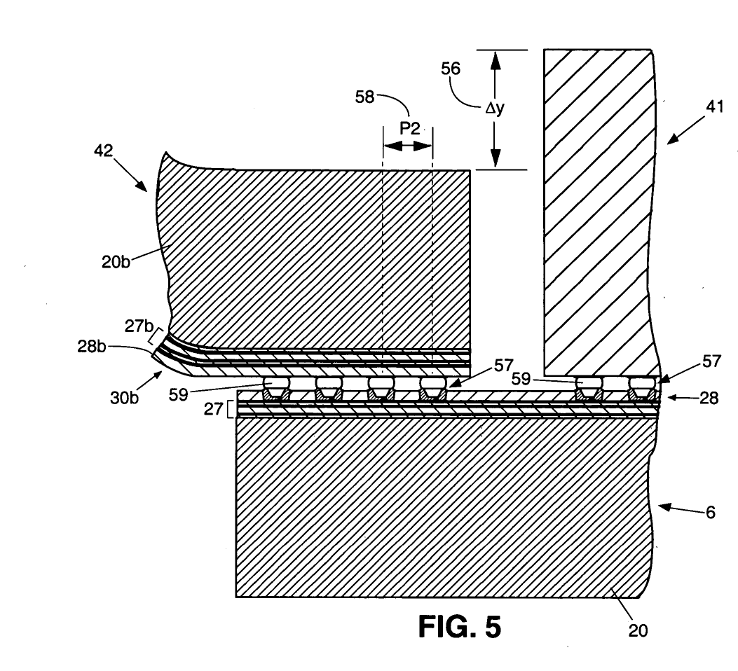

FIG. 5 is an expanded view of section CC of FIG. 4, showing that there can be sufficient height available for connecting a cable to an attachment site on a surface of the SIP. For example, if 1 oz copper foil 20b having a thickness of 34 microns is employed as the conductive substrate for cable 42, and if microprocessor chip 41 of FIG. 4 is thinned to 150 microns, then a clearance (Δy) 56 of approximately 90 microns is available. The flip chip bonding attachments (attachment sites) of microprocessor chip 41 and cable 42 of FIG. 4 both employ the same bump/well connections 57 as shown. The attachment pitch (P2) 58 of bump/well connections can be 100 microns or less in the preferred embodiment. Multi-layer circuit 30b of cable 42 includes an interconnection circuit 27b that is similar to interconnection circuit 27 of the SIP as defined in FIG. 2; the special assembly layer 28b of multi-layer circuit 30b includes gold stud bump terminals 59 rather than the wells more typically provided in special assembly layer 28 of the SIP.

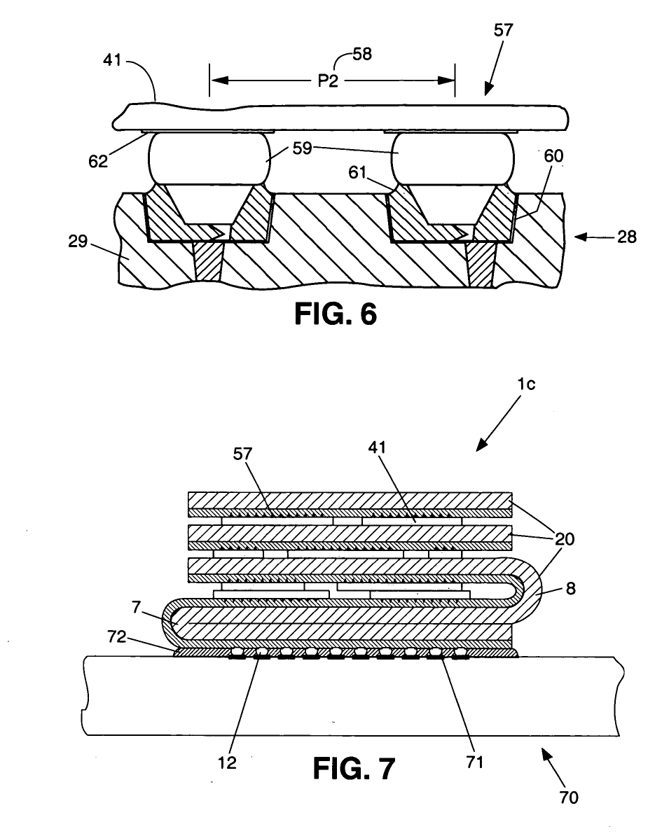

FIG. 6 is an expanded cross-sectional view showing a pair of bump/well attachments 57, as introduced in FIG. 5. Gold stud bumps 59 are inserted into wells 60 containing solder 61. Using a preferred gold wire diameter of 18 microns, both the diameter and the height of stud bumps 59 can be approximately 50 microns. Such gold stud bump configurations can be produced using the WaferPro bonder from Kulicke & Soffa, Willow Grove, Pa., USA. These dimensions for stud bumps 59 make it possible to have a pitch for the input/output connections (P2) 58 of 100 microns or less. Bump/well connection 59 is mechanically strong and can withstand shear forces arising from the different expansion characteristics of chip 41 (FIG. 4) versus substrate 20 of FIG. 2, without requiring an epoxy underlayer. This resistance to shear force is achieved because the wells are firmly imbedded in dielectric material 29 of FIG. 6, and the stud bumps 59 of FIG. 6 are also firmly attached to their I/O pads 62 using the well-proven ball bonding method. Elimination of the epoxy underlayer removes a major impediment to rework that may be required for replacing a defective chip. Removal of a defective chip consists of heating the conductive substrate to a temperature below the melting point of solder 61, applying-hot inert gas to the assembled chip until solder 61 melts, and withdrawing the bumps 59 from the wells 60. Touchup may include cleaning the surface around the wells, and topping up the solder in the wells using a squeegee. Then a new component can be selected, aligned, and inserted and the SIP retested, as will be further described. Although other types of bumps may be employed in the current invention, gold stud bumps are preferred for their small size, high conductivity, mechanical compliance, and low fabrication cost.

Before folding substrate 20 to form a stacked package, all of the components are attached, tested, and reworked as necessary. A substrate like 1 of FIG. 1 can be folded in many different ways. The electrical performance and the cooling performance are not particularly sensitive to the order of folding because the electrical path lengths and cooling path lengths are largely independent of the folding order, except for variations in the hinge lengths such as 7-10 of FIG. 1. A portion of copper substrate 20 underlies each of the assembled components (providing tight thermal coupling between assembled components) and the substrate can provide a direct thermal path to external heat sinks, if any (providing tight thermal coupling of the whole assembly to the outside heat sink). It may be required that one of the delineated surfaces include an attachment site for connecting to the underlying board. Also it may be advantageous for the topmost layer to be an exposed copper surface, to provide the lowest impedance thermal path to external heat sinks. Furthermore, particular chips or other assembled elements may produce a great amount of heat, or be particularly heat sensitive, and resolution of these issues together with optimization of electrical performance factors will determine the preferred order of folding. FIG. 7 illustrates a folded version 1c of assembly 1b of FIG. 4, with hinges 7 and 8 of FIG. 1 showing in the cross-section. All of the chips such as 41 are preferably attached using bump/well connections 57. Copper substrate 20 is shown folded, and solder bumps 12 of FIG. 1 connect the SIP to a circuit board 70. In this example, circuit board 70 is fabricated using conventional materials such as FR-4. Lands (conductive pads) 71 are provided on circuit board 70 for each solder bump 12; the lands correspond to input/output terminals of the board, and the solder balls 12 correspond to input/output terminals of the SIP. As previously discussed, this package attachment method typically requires an epoxy underlayer 72 between SIP 1c and board 70, to strengthen the interface and prevent cracking at or near the solder bumps due to thermally induced stresses. While underlayer 72 is effective in reducing or eliminating thermally induced cracking, it is difficult to remove if rework is required.

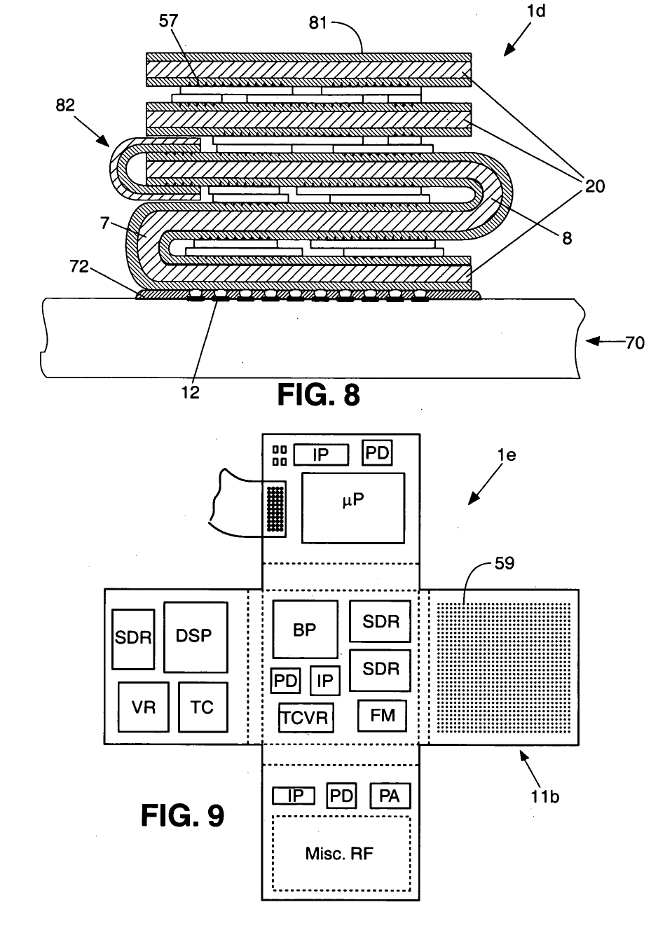

FIG. 8 illustrates another embodiment of the current invention wherein components are attached on both sides of conductive substrate 20 to form a 2-sided SIP configuration 1d. Using a 2-sided board may or may not result in improved functional density compared with a 1-sided board, depending on the application and the attached microelectronic elements. The top surface 81 is preferably clear of chips so as to provide a flat surface for good thermal connection to an external heat sink. Again, all chips are preferably attached using bump/well connections 57 of FIGS. 5 and 6. A short cable 82 is shown as an example of a high-density cable using bump/well connections that provides signal and/or power paths between layers of an SIP.

FIG. 9 illustrates an alternative version 1e of assembly 1b of FIG. 4 having an attachment site 11b comprising an array of closely spaced gold stud bumps 59 in place of solder balls 12 of FIG. 4. As previously discussed, the gold stud bumps are preferred because they provide finer pitch (100 microns or less). Together with their corresponding wells, they also provide improved reworkability of defective chips.

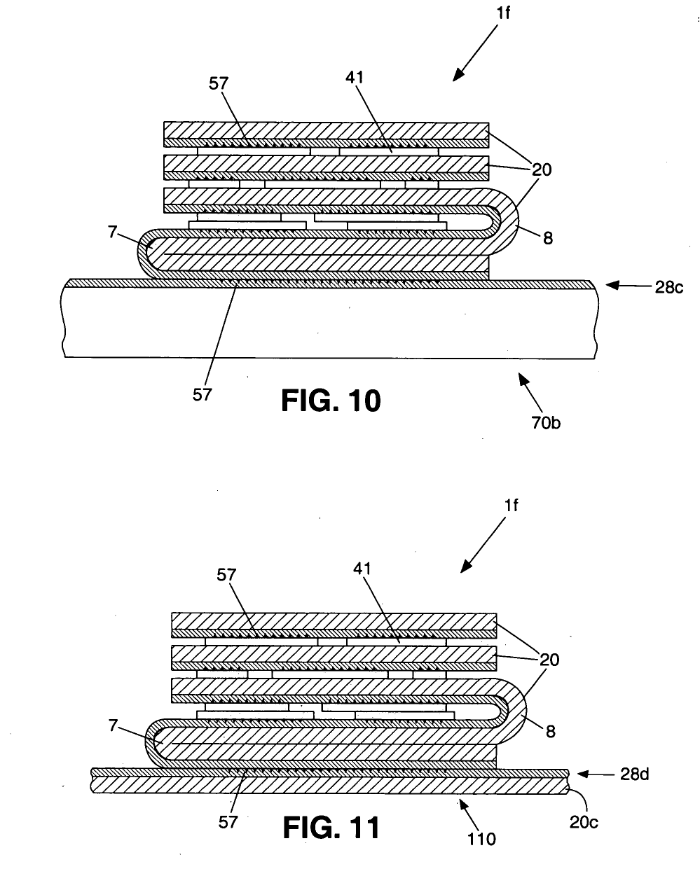

FIG. 10 shows a folded version 1f of assembly 1e of FIG. 9, attached to a printed circuit board 70b that is built from conventional materials except that it includes a special assembly layer 28c. Special assembly layer 28c includes wells like 60 of FIG. 6 for accepting stud bumps 59 to form bump/well connections 57 at the interface between SIP 1f and board 70b.

FIG. 11 is like FIG. 10 except that circuit board 70b has been replaced with a circuit board 110 fabricated on a copper substrate 20c, in a manner similar to the fabrication of circuit board 1 of FIG. 1, described for use as an SIP substrate. This configuration has the advantage that copper substrate 20c is a good thermal conductor; it is in close proximity to folded copper substrate 20 and since it is one-sided, it can be easily attached to an external heat sink. Circuit board 110 includes special assembly layer 28d, providing wells 60 of FIG. 6 for mating with stud bump terminals 59 provided at the base surface of SIP If, forming bump/well connections 57.

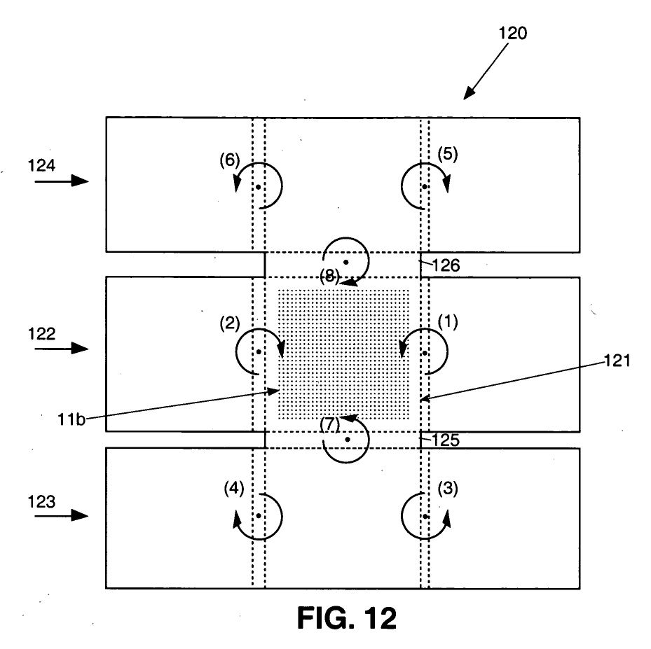

FIG. 12 introduces an SIP 120 of the current invention having 9 delineated surfaces that can be folded to create a 9-high stack. At the bottom of the center surface 121 a preferred attachment site 11b comprising an array of closely spaced stud bumps 59 (FIG. 5) is provided for connecting SIP 120 to a circuit board (attachment site 11b is shown grayed in the figure.). The delineated surfaces are arranged in three rows 122-124. Rows 122 and 123 are linked by hinge 125, and rows 122 and 124 are linked by hinge 126. As before, all assembly, test and rework is performed while SIP 120 is in planar form; then the surfaces are folded to form stacked layers of the SIP. The center row 122 is folded first, then row 123, and finally row 124. The preferred folding order of the surfaces is indicated by rotational symbols labeled (1)-(6). After the three rows have been folded, the assembly is folded at hinge 125, and finally at hinge 126. After folding, each delineated surface becomes a layer of the SIP.

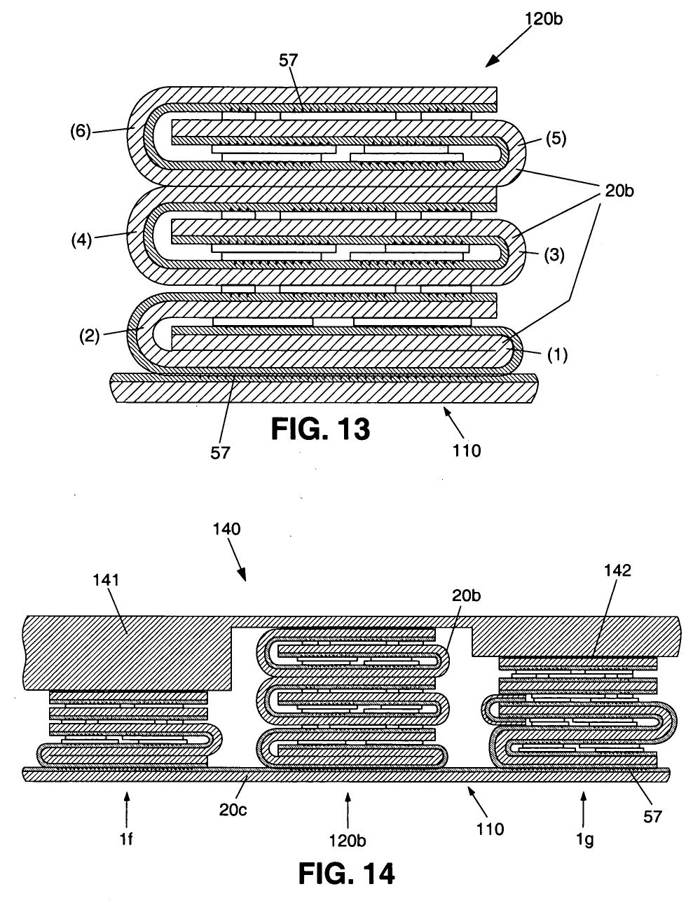

FIG. 13 illustrates the folded version 120b of SIP 120. SIP 120b is assembled with a full set of components, potentially on one or both sides although 120b is one-sided in the figure, and preferably uses bump/well connections as previously described. It is tested and reworked in planar form as is preferred for all variations of the current invention. The order of the first 6 folds is shown, corresponding to the order shown in FIG. 12. Substrate 20b is copper as before (or an alloy of copper), and has 9 folded layers corresponding to the 9 delineated surfaces of FIG. 12. All of the attachment sites within the stack and between SIP 120b and board 110 (FIG. 11) are preferably comprised of bump/well arrays as shown.

FIG. 14 illustrates a mechanically rugged and thermally efficient assembly 140 that includes SIPs 1f of FIG. 10, 120b of FIG. 13, and 1g. SIP 1g is similar to SIP 1d of FIG. 8 except that the attachment site for connecting to board 110 employs gold stud bumps 59 rather than solder balls 12 of FIG. 1. As previously described, each component within each SIP is thermally coupled to a copper foil substrate such as 20b. Each of the SIPs in the figure is thermally coupled at its base to board 110 (FIG. 11) which preferably includes copper substrate 20c. Additionally, each SIP may be thermally coupled to a top copper member 141 using a thermal interface layer 142 such as thermal grease. Top copper member 141 can be milled to create varying thickness as shown, to accommodate the varying heights of the SIPs. Assembly 140 is mechanically rugged because of the protection afforded by copper members 110 and 141. Large amounts of heat can be extracted from assembly 140 using the top and bottom plates as interfaces to external heat sinks. The external heat sinks may contain circulating cooling fluids for example.

Having described several preferred SIP embodiments, this application will now focus on manufacturing methods and preferred equipment for fabricating them.

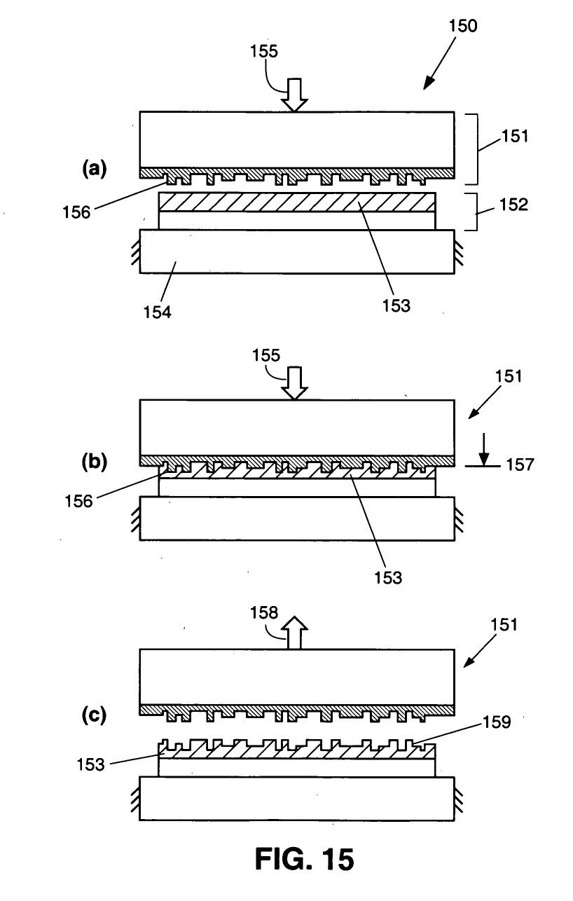

FIG. 15 illustrates an imprinting scenario. FIG. 15(a) shows an embossing machine or apparatus 150 including an embossing tool 151 that is positioned in vertical opposition to a substrate 152 including a topmost layer of imprintable material 153. In FIG. 15(a) substrate 152 is fixed on a support structure 154; however, either side can be fixed. A normal force 155 is applied as shown, and it can be applied to either the tool or the substrate, whichever one is not fixed in position. Embossing tool 151 has embossing features 156 which will impart a three-dimensional image in the layer of embossing material 153. “Embossing tool”, “imprinting tool” and “stamp” are synonymous in this application. FIG. 15(b) illustrates an imprint cycle wherein embossing features 156 are pressed into the layer of imprintable material 153 by the normal embossing force 155. Embossing tool 156 may be heated to facilitate plastic flow of imprintable material 153. A limit stop 157 is shown, representing the desired maximum travel of imprinting tool 151. FIG. 15(c) illustrates the completion of the imprint cycle wherein a releasing force 158 causes tool 151 and substrate 152 to separate, leaving a negative image 159 of the embossed features in the layer of imprintable material 153. The process illustrated is a dual damascene process because there are two depths of the imprinted image.

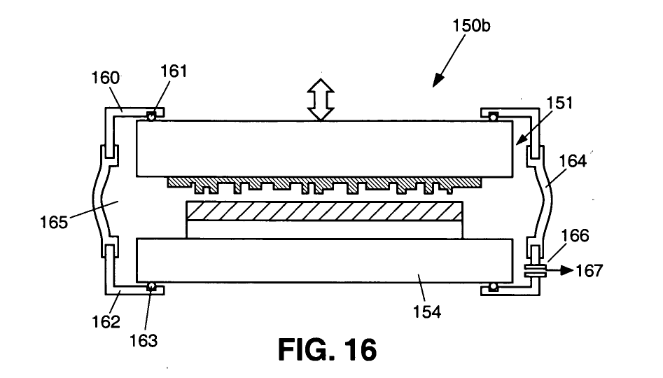

It is difficult to expel air between flat surfaces as they approach with a separation of a few microns. Consequently, it is usually desirable to evacuate air from the chamber containing the tool and the substrate. An arrangement for accomplishing this is schematically depicted in FIG. 16. Embossing machine 150b includes a top circular bracket 160 that is sealed using an O-ring 161 to the top surface of stamp assembly 151 of FIG. 15. Similarly, a bottom circular bracket 162 is sealed using O-ring 163 to the bottom surface of support structure 154. Top and bottom circular brackets are connected using a cylindrical flexible membrane 164, which allows relative motion between the stamp and the substrate while vacuum is maintained in the chamber 165. Such relative motion is required to accommodate the stamping stroke and may also be required for small lateral motions to achieve alignment of the tool and the substrate. A vacuum port 166 is provided for evacuating air 167 using a vacuum pump (not shown).

If the embossing tool can be produced efficiently and inexpensively, this will accelerate the acceptance and viability of the imprinting method. Shortening new product development cycles is also important. Since the time to develop a new product is typically gated by the need to procure tooling, and since the turnaround time for photo tools is typically several days and the turnaround time for embossing tools is typically several weeks, there is motivation to make the production of imprinting tools more efficient. Accordingly, the current invention includes a method for fabricating embossing tools or stamps using a subset of the equipment for the imprinting process; this subset includes an optical mask aligner with UV exposure, an electroplating system, and a CMP polisher. Photo masks are also required. However, for faster turnaround it is also possible to use maskless exposure systems such as the S56-HR manufactured by Ball Semiconductor, Inc., Texas, USA. The registration accuracy of the S56-HR is ±2 microns, which is adequate to make embossing tools of the current invention.

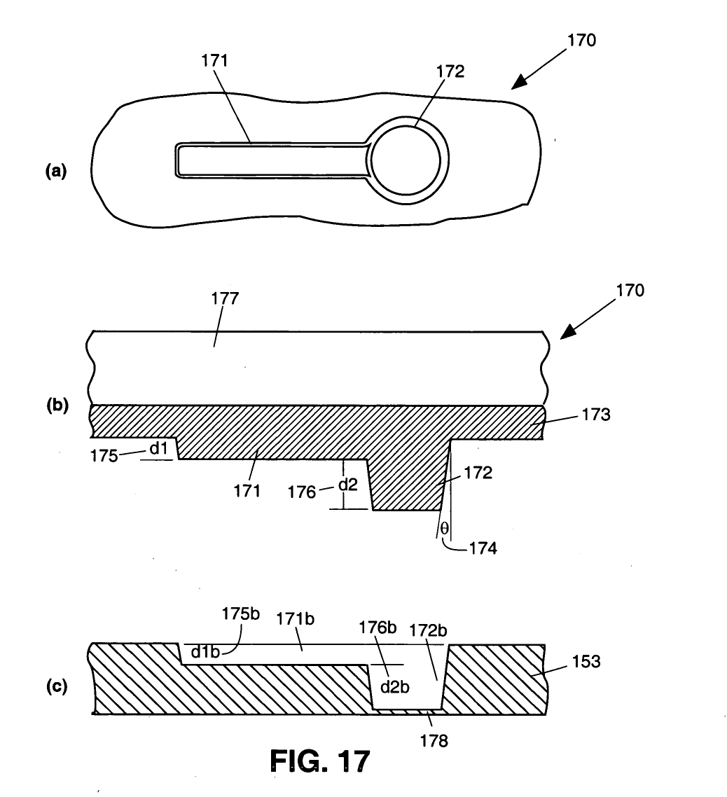

FIG. 17 illustrates the basic geometries for imprinting a dual damascene circuit. FIG. 17(a) is a top view of an embossing tool fragment 170 including a trench feature 171 and a via feature 172. FIG. 17(b) shows fragment 170 in cross-section. A hard embossing material such as nickel 173 includes a raised trench feature 171 and a raised via feature 172, with the via feature at a greater depth than the trench feature. The sidewalls of features 171 and 172 preferably have a positive taper angle θ 174, preferably around 5 degrees to the vertical; this positive taper helps to enable a smooth release when the stamp is being separated from the imprinted material. For good tool life, embossing material 173 must be hard compared with the hardness of the material to be imprinted at the chosen embossing temperature. Layer 173 containing the embossing features is bonded to a suitable carrier 177, formed from a transparent material (for alignment purposes) that can withstand the selected embossing temperature. FIG. 17(c) shows typical characteristics for trench and via features imprinted by tool fragment 170. These characteristics depend on the spreading properties (dynamic viscosity) of the imprinted material 153 of FIG. 15 at the embossing temperature. However, it is typical for trench features to imprint faithfully, that is depth. 175 equals depth 175b (d1=d1b), and for the deeper via features to imprint less perfectly, with a thin web of material 178 left behind; i.e., depth 176b<depth 176 (d2b<d2).

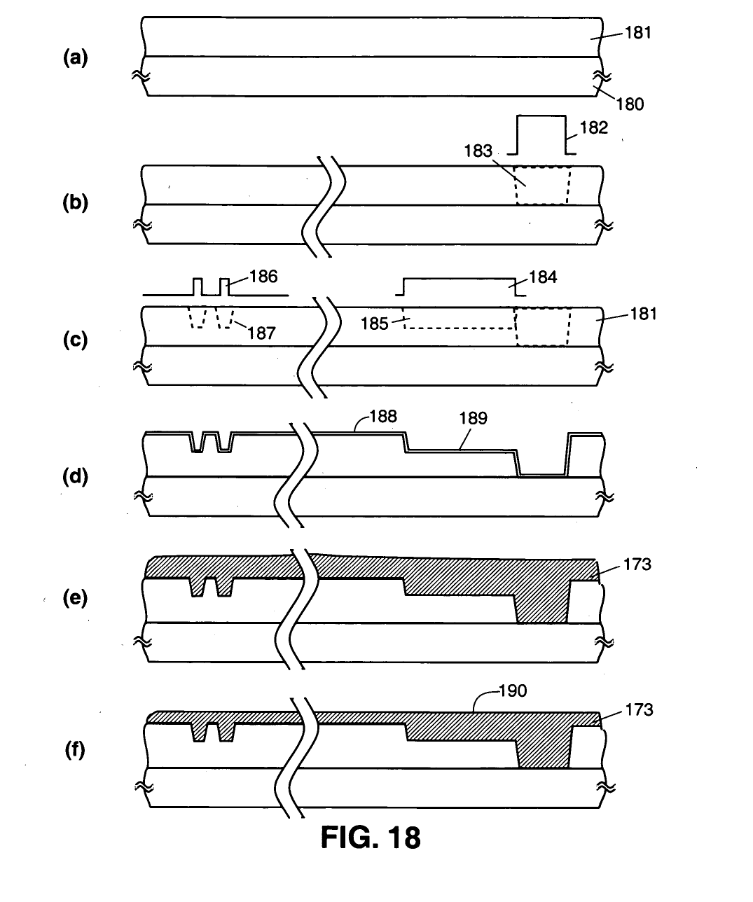

FIG. 18 shows a first sequence of process steps for creating an embossing tool of the current invention. In FIG. 18(a) a temporary carrier 180 has been coated with a photo resist material 181, preferably using a spin coating method. Carrier 180 may be a silicon wafer for example, for the case of a wafer form factor. Resist 181 is preferably a positive thick film resist that can be patterned with fine control of the sidewall angle corresponding to positive taper angle θ 174 of FIG. 17. Such a resist is manufactured by Tokyo Ohka Kogyo, Kanagawa Prefecture 211-0012, Japan. Control of the taper angle is described by Yoshihisa Sensu et al, .“Study on Improved Resolution of Thick Film Resist (Verification by Simulation)”. In FIG. 18(b) ultra violet (UV) light with an intensity profile 182 has been projected through a first optical mask to expose a localized cylindrical volume 183, to a depth corresponding to the desired via depth. In FIG. 18(c) a second exposure having intensity profile 184 has been projected through a second optical mask to expose localized region 185, corresponding to a trench feature. As part of the second exposure, intensity profile 186 preferably exposes localized volumes 187 as shown, to aid in the fabrication of alignment features. Typically, these alignment features will be located at the periphery of the tool area. Note that exposure intensity 182 is greater than exposure intensity 184; the exposure doses are matched to the desired depths shown in the figure. Exposed regions 183, 185, and 187 are developed to remove the volumes shown in dotted outline. After developing, rinsing, and drying resist 181 the surface is sputter coated with a seed layer of nickel 188, as shown in FIG. 18(d); use of an adhesion layer like titanium under the nickel is preferably avoided because the surfaces are later required to separate at this interface. Profile 189 of the trench feature is shown. FIG. 18(e) shows the result of electroplating embossing material 173 of FIG. 17 as shown; the preferred embossing material of the current invention is nickel. Nickel is much harder than Cytop at the embossing temperature of 220° C., and the expected life of the nickel tool is of the order of 100,000 imprints. Techniques known in the art are preferably used to ensure densely plated structures with void-free features; these techniques include the use of layered plating liquids, and periodic pulse-reversing power supplies. In FIG. 18(f) nickel surface 190 has been planarized and polished by a CMP polishing step, as is known in the art.

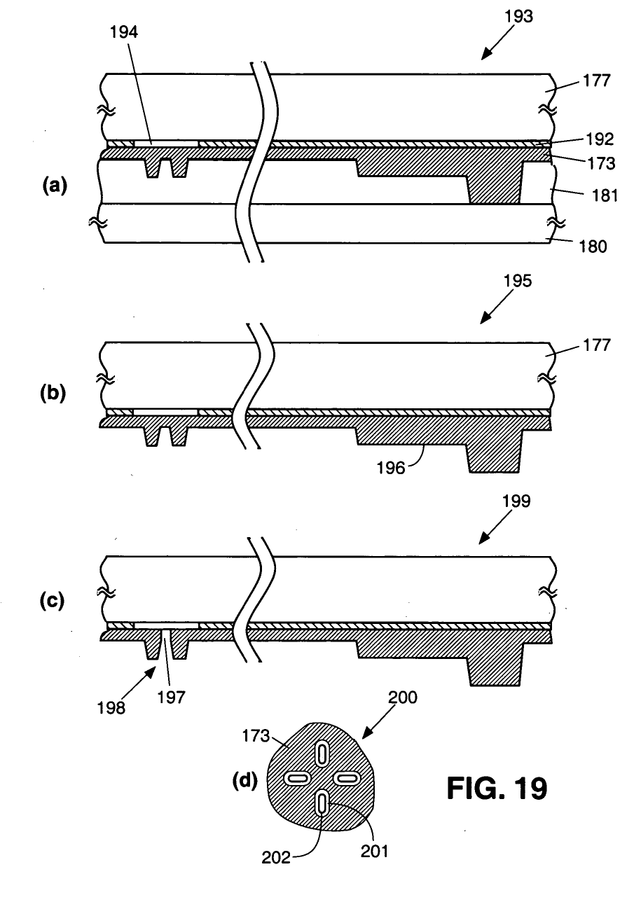

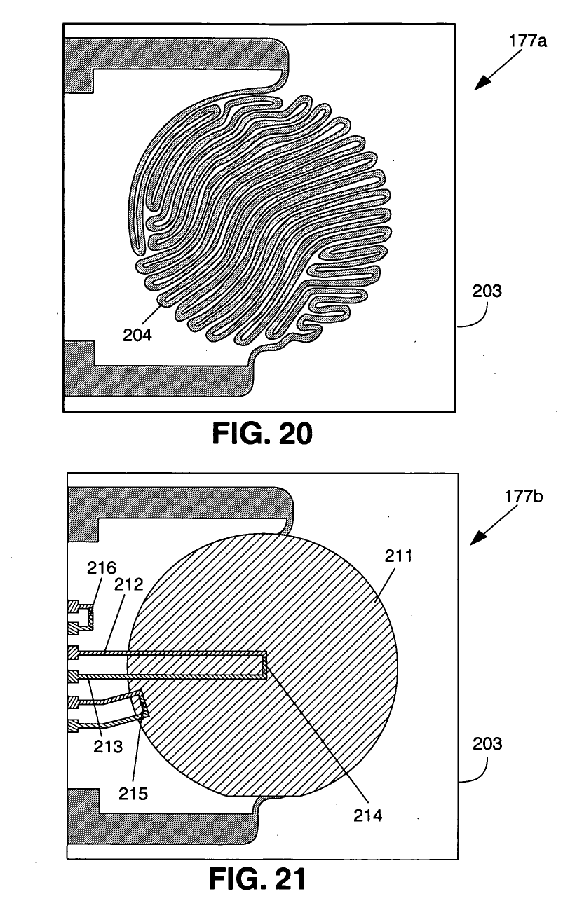

FIG. 19(a)-(c) shows a second sequence of process steps that follow the first sequence of FIG. 18 in order to create an embossing tool of the current invention. In FIG. 19(a) a suitable embossing tool carrier 177 of FIG. 17 has been bonded to embossing layer 173 using a solder material 192, thus creating un-separated bonding tool 193. The preferred material for carrier 177 is quartz that has been coated with a solder-wetting layer of copper except for regions 194 near the alignment targets. Prior to lamination the preferred solder has the form of a dry sheet with stamped holes and is comprised of 80% gold and 20% tin, having a eutectic melting temperature of 280° C. This melting temperature is higher than the preferred embossing temperature of 220° C., but not too much higher, to reduce thermal mismatch effects that can lead to bowing of the embossing surface. Tool carrier 177 is bonded to nickel surface 190 by melting and cooling solder 192. Removing temporary carrier 180 of FIG. 18 together with resist layer 181 creates separated embossing tool 195, as shown in FIG. 19(b). As will be further described, the preferred embossing carrier will be equipped with a power resistor and thermocouples fabricated as thin film structures on the quartz carrier. By using these to thermally cycle un-separated embossing tool 193, thermal stress can be induced at the interface between embossing layer 173 and temporary carrier 180 (carrier 180 is preferably cooled while embossing layer 173 is heated). This stress will initially cause cracking at the photo resist interface, and ultimately will cause separation of embossing tool 195 from resist layer 181. After separation, any organic residues remaining on surface 196 are preferably removed by an oxygen plasma etch. Finally, in FIG. 19(c), a wet nickel etch is preferably used to remove a small amount of nickel 197 at the center of each set of alignment features 198. This provides an optical path through embossing tool 199 of the current invention, at each alignment target. FIG. 19(d) shows a preferred alignment arrangement 200, as viewed by an alignment operator during the setup for an embossing cycle. Embossing material 173 of FIG. 17 has clear areas 201. Inside of each clear area 201 is a mark 202 that is preferably etched in the copper substrate of the circuit being embossed, as will be further described. For proper alignment, mark 202 is centered in clear area 201.

We shall now consider the method for fabricating a power resistor and thermocouples on embossing tool carrier 177 of FIG. 17. FIG. 20 shows a blank quartz substrate 203 that is preferably rectangular and 0.5-0.6 mm thick, on which a thin film power resistor 204 has been fabricated, to create version 177a of the embossing tool carrier. To fabricate resistor 204, substrate 203 is coated with resist and patterned so that resist remains only where the thin film resistor will be absent. The patterned substrate is then coated with an adhesion layer of titanium, plus gold to a thickness of around 0.5 microns, creating a sheet resistivity of approximately 10 mΩ/square. The resist is swelled in developer to implement a lift process for patterning power resistor 204. Preferably resistor 204 has around 600 squares and a resistance of approximately 6Ω. When heat is required during an embossing cycle, or when thermal cycling is used to create separation from temporary embossing tool carrier 180, an applied voltage of 55V will generate approximately 500 W of power.

In FIG. 21 power resistor 204 of FIG. 20 has been coated with an insulating layer of silicon oxy-nitride (SiOₓN_{y}) 211 through a mechanical mask. Layer 211 provides electrical isolation between the gold of power resistor 204 and thermocouple structures to be fabricated on top. Each thermocouple is formed using an adhesion layer of titanium plus an overlapping region of thin film palladium 212 and thin film platinum 213, as described by Kreider et al. It will be useful to monitor the rate of temperature stabilization as well as the maximum temperature of the embossing tool, so a probe site near the center 214 and one near the edge 215 of power resistor 204 are included. Probe 216 near the edge of quartz substrate 203 provides a reading of background temperature in the imprinting chamber, and a limit may be set for reliable equipment operation. After the thermocouples have been formed, another passivating layer of SiOₓN_{y} is deposited, forming a base layer for the embossing features, which are fabricated as previously described in relation to FIGS. 18 and 19.

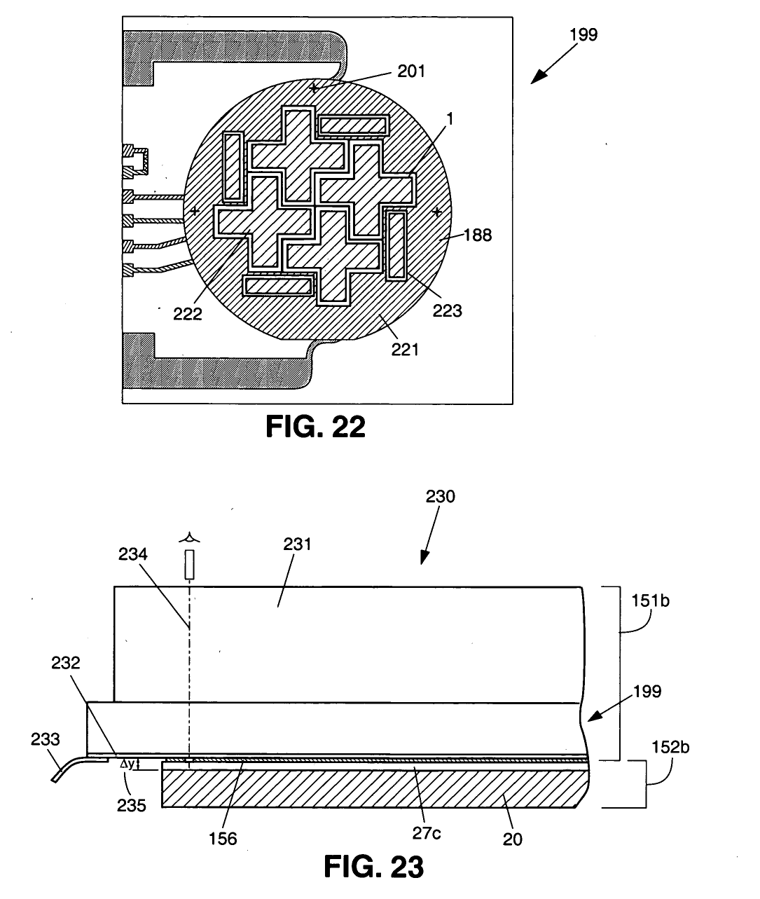

FIG. 22 shows completed embossing tool 199. In this case a 300 mm wafer has sufficient area-to place four copies of foldable circuit board 1 of FIG. 1 (the edge dimension of each delineated surface is 38 mm in this case). Alignment targets 201 of FIG. 19 are fabricated in embossing layer 173 of FIG. 17 as shown; since they don't require an independent alignment there is zero alignment error in relation to the other embossing features 222. Some rectangular areas 223 at the outer periphery of the wafer area may be utilized to fabricate high density cables, as will be further described.

The current invention expands the capabilities of existing laminating machines to include several co-resident functions: a normal force 155 (FIG. 15) for imprinting; means for accurately aligning each new layer to the preceding layer; and means for selectively heating only the topmost dielectric layer. FIG. 23 illustrates such an alignment means. An edge portion of an alignment stack 230 is shown as an example, including a variation of embossing tool 151b and substrate 152b, sized for a 300 mm wafer format. A top glass member 231 is approximately 14 inches square and 0.2 inches thick. Embossing tool 199 of FIG. 19 is positioned underneath the top glass member with thin film circuits (power resistor and thermocouples) 232 and embossing features 156 of FIG. 15 as shown. Wired connections to power resistor 204 (FIG. 20) and thermocouples 214-216 (FIG. 21) are shown as 233. Substrate 152b includes a copper base layer 20 as in FIG. 2, and an interconnection circuit in progress 27c. Alignment between embossing tool 199 of FIG. 19 and copper base layer 20 is preferably achieved using an objective and eyepiece positioned above alignment axis 234, with a clear light path along this axis. A preferred alignment image as viewed by the operator is shown in FIG. 19(d). Positioning systems having fine adjustments are required, as are available on wafer aligners such as the 1×full field lithography (1XFFL) wafer aligner produced by Suss Microtek, Germany. For implementing the current invention the desired layer to layer alignment accuracy is ±2 microns, and the vertical gap (Δy) 235 between corresponding alignment marks on embossing tool 199 and copper substrate 20 is approximately 30 microns in this preferred embodiment.

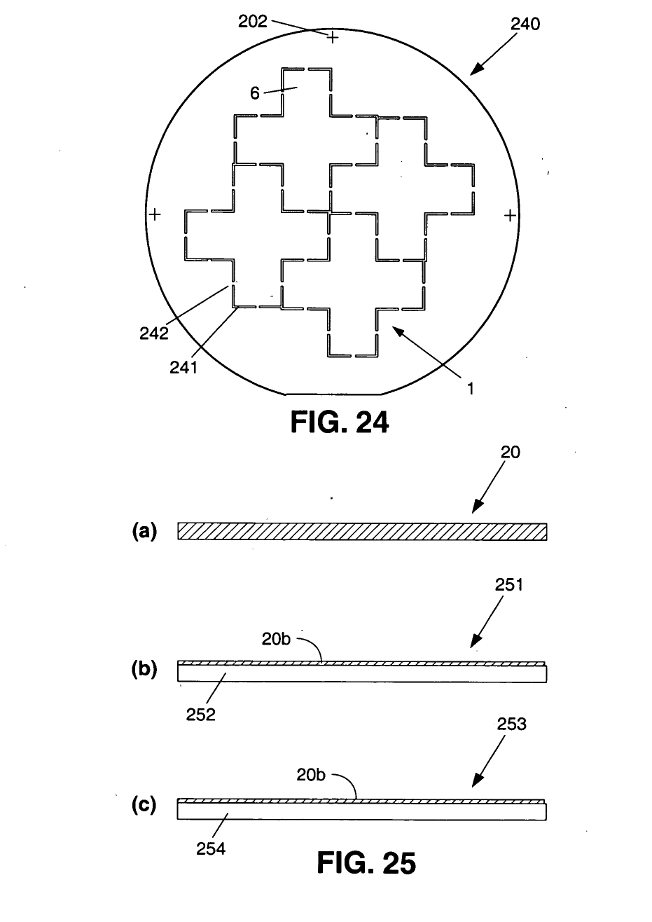

FIG. 24 shows a copper wafer 240 that has been etched to form a conductive substrate for four foldable circuit boards 1. Channels 241 are etched through the copper to create delineated surfaces such as 6 that will later be folded to form a stacked arrangement. Etched channels 241 are not continuous; bridges of continuous copper 242 remain so that each of the delineated surfaces will remain attached to and in the plane of wafer 240. Bridges 242 will later be removed using a diamond saw, with wafer 240 mounted on dicing tape to a dicing chuck, as is known in the art. To prevent oxidation during processing and provide better adhesion of subsequent organic coatings, copper wafer 240 is preferably coated with a thin layer of chromium. Alignment marks 202 of FIG. 19 may be etched in the copper, or patterned in the chromium surface using laser ablation.

The total substrate thickness needs to be at least 0.5 mm for ease of polishing using standard CMP equipment. Since some preferred SIP embodiments utilize copper substrates having a thickness less than 0.5 mm (for example 69 microns or 0.069 mm in the case of 2 oz copper foil), carriers may be used to support the thin foils. For wafer form factors, the carriers may be semiconductor wafers; for flat panels they may be rectangular glass panels up to approximately 2 meters on a side. FIG. 25 illustrates preferred substrates for SIPs, high density cables, and printed circuit boards of the current invention. FIG. 25(a) shows a single copper substrate 20 of FIG. 2 having a preferred thickness of 0.5-1.7 mm and no carrier. FIG. 25(b) shows substrate 251 having a 2 oz copper foil 20b carried on a silicon wafer 252 having a preferred thickness of 0.5-0.6 mm. FIG. 22(c) shows substrate 253 in the form of a 2 oz copper foil 20b on a glass panel 254 having a preferred thickness of 1.1-1.7 mm. The preferred form of copper for substrates 20, 20b, 20c, 20d is dispersion-strengthened copper, DSC. DSC is approximately ten times stronger than pure copper, but its electrical and thermal conductivity is almost the same as pure copper. A solder release layer is preferably employed between the carrier and the copper foil. For example, Indalloy 183 comprising 88% gold and 12% germanium may be used, with a eutectic melting temperature of 356° C. A low temperature solder may also be used, even one that melts during each imprint cycle. In this case, frictional forces will prevent lateral movement of the carrier, and stress in the carrier/foil combination will be released, alleviating any tendency for the carrier plus foil combination to bow at the embossing temperature.

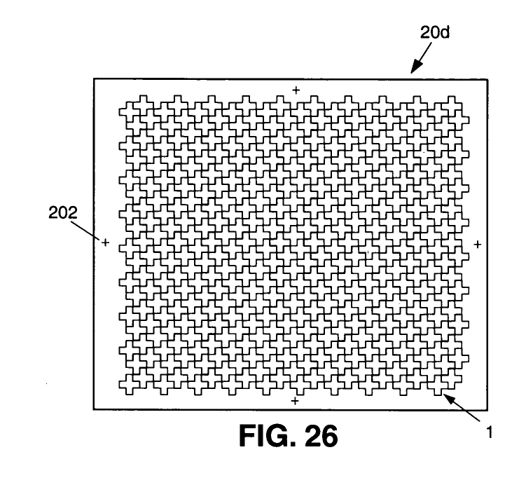

FIG. 26 illustrates the option of fabricating SIPs of the current invention using a flat panel form factor. It shows a top view of a copper substrate 20d that measures 1870 by 2200 mm. Glass panels of this size are currently used in the manufacture of flat panel displays. Etch patterns delineating 490 copies of foldable printed circuit board 1 are depicted in the figure, along with copper alignment targets 202 of FIG. 19. This large number of substrates can lead to the lowest possible manufacturing cost per substrate. Typically, test devices, prototypes and early production SIPs will be manufactured on substrates in a wafer format like 240 (FIG. 24), with large panels like 20d reserved for high volume production. The preferred substrate/carrier combination for large panels is shown in FIG. 25(c). The preferred method for providing heating and temperature sensing circuits for flat panels is to fabricate one or more power resistors plus multiple thermocouples on the glass carrier, using fabrication techniques similar to those described for wafers.

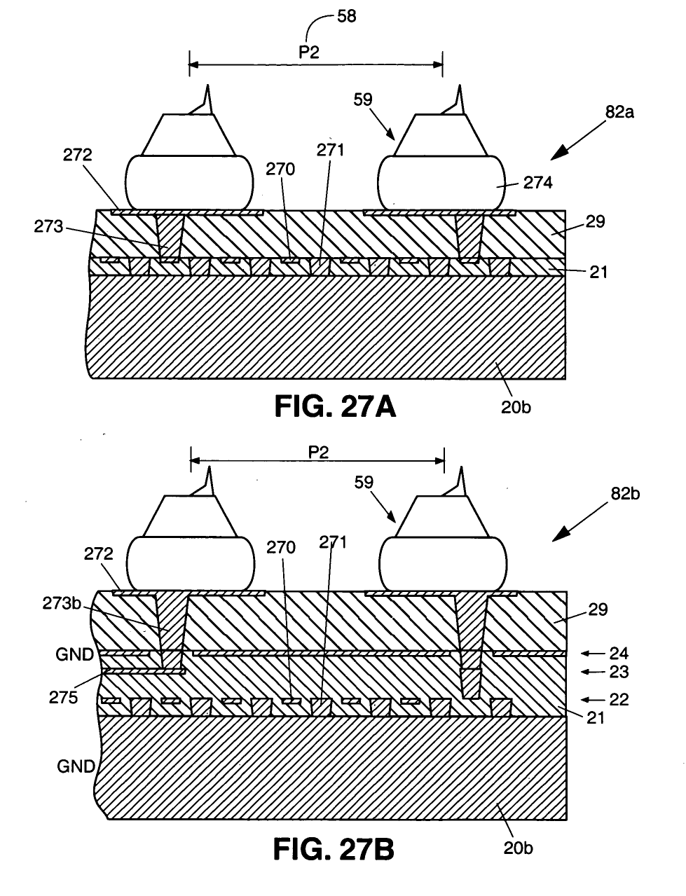

High-density cables can be manufactured using the same techniques described herein for SIP substrates, interconnection circuits, and special assembly layers. These cables may include traces with controlled impedance for high-frequency operation, and the terminals at each end may be spaced with a pitch as small as 100 microns or less. A cross-sectional view of high-density cable 82a is shown in FIG. 27A. Cable 82a is similar to cable 42 of FIGS. 4 and 5 except that it does not include signal cross-overs, and thus it can be implemented with two imprinted layers instead of four. Such a simple 1:1 connection may be appropriate for routing high-speed differential signals between the layers of stacked assembly 1d of FIG. 8, for example. Cable 82a includes conductive substrate 20b at GND potential and signal traces 270 arrayed between vias 271 connected to GND, thus creating transmission lines having controlled impedance within dielectric material 21 of FIG. 2 (preferably Cytop). Attachment sites at each end of cable 82a include gold stud bump terminals 59 of FIG. 5, having a pitch P2 58 of 100 microns or less. Terminals 59 are bonded to input/output pads 272 that connect using vias 273 to signal traces 270. Ball bond 274 is preferably formed by the application of pressure, heat, and ultrasonic energy, as is known in the art. Wells 60 of FIG. 6 filled with solder 61 may be fabricated in place of stud bumps 59, depending on what cable 82a is connecting to.

FIG. 27B illustrates high-density cable 82b that includes four imprinted layers instead of two layers, and can accommodate signal cross-overs (required for different pin assignments at each end of the cable). Layers 22-24 are shown as defined in FIG. 2, the same layers as for an interconnection circuit 27 of an SIP of the current invention. Openings in the ground plane, layer 24, are provided for signal vias such as 273b to connect signal traces such as 275 to input/output pads 272. Both cable 82a of FIG. 27A and cable 82b can be formed into unique three-dimensional paths for convenient routing between pairs of microelectronic elements in a system, by taking advantage of the ductile properties of copper foil 20b. Cables 82a and 82b may have more than two ends, i.e. multiple branches, for connecting between more than two elements in a system.

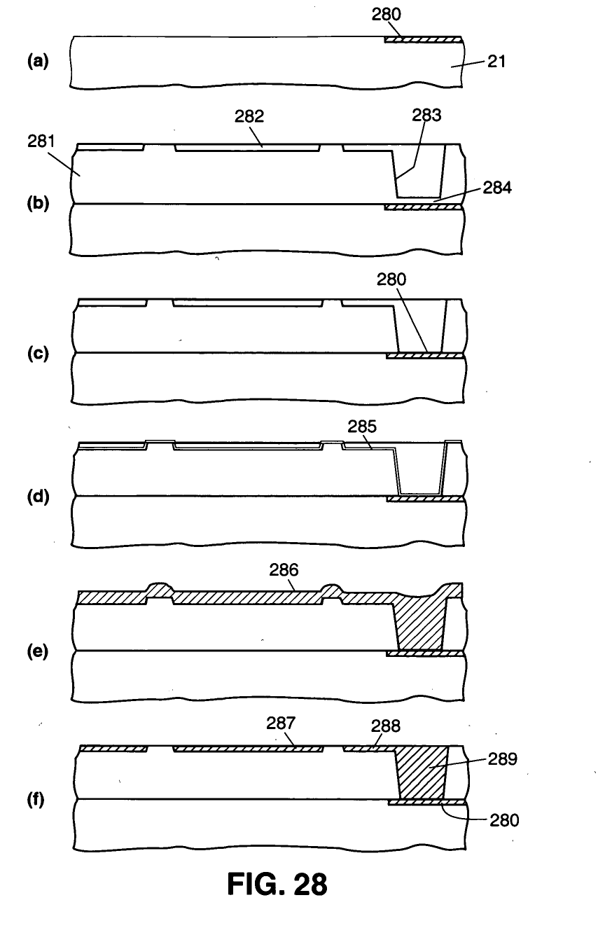

FIG. 28 is a sequence of cross-sectional views that summarizes the imprinting, plating, and CMP processes employed to fabricate SIPs of the current invention. FIG. 28(a) shows a partially completed interconnection circuit of the current invention having a polished surface and an exposed copper trace 280 embedded in dielectric layer 21 of FIG. 2. FIG. 28(b) shows that a new dielectric layer 281 has been spun onto the exposed surface and cured. This new dielectric layer is the “topmost layer”. FIG. 28(b) also shows that an imprint cycle has been performed; trench impressions 282 and via impressions 283 have been impressed in topmost layer 281. A web of material 284 typically remains after an imprint cycle. A dry plasma etch is used to remove this web and expose the underlying copper trace 280, as shown in FIG. 28(c). An adhesion layer of titanium and a seed layer of copper 285 are sputtered onto the surface, as shown in FIG. 28(d). FIG. 28(e) shows the result of electroplating the seed copper, forming an irregular copper surface 286 as shown. Special electroplating techniques known in the art are employed to achieve void-free copper that fills the trench and via impressions as shown; the techniques include layering of the chemical plating bath and periodic pulse-reversing power supplies. These techniques provide the capability of plating “from the bottom up”, thereby avoiding seams and voids. FIG. 28(f) shows the result of a CMP step to planarize and polish the surface, forming polished feature 287 and trace 288 connected to via 289 as shown. For improved adhesion between layers, it is typically desirable to have some surface; roughness (rather than a mirror surface finish); consequently the SMP parameters are chosen to achieve the desired thickness dimension together with a controlled amount of surface roughness, as is known in the art. The bottom of via 289 forms a low resistance contact with trace 280 of the prior layer. If another circuit layer is required, the process is repeated by spin coating a new layer of dielectric material on-top and repeating the imprint cycle.

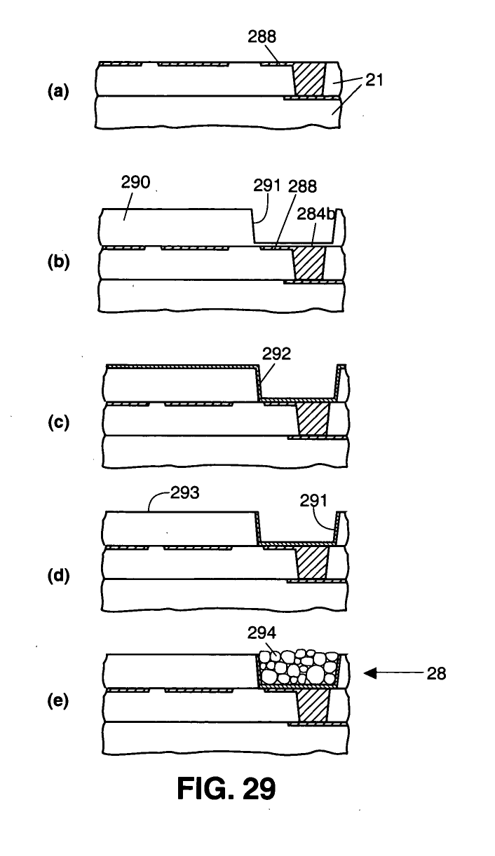

FIG. 29 shows a summary of the additional process steps to create the special assembly layer 28 of FIG. 2. FIG. 29(a) shows the result of previous processing, including a polished surface with exposed trace 288. Dielectric material 21 of FIG. 2 is also shown. FIG. 29(b) shows that a new layer of dielectric material 290 has been spun on to the surface and cured. A well 291 similar to well 60 has been impressed into dielectric material 290 by an embossing tool, and a thin web 284b of dielectric material still covers trace 288, preventing good electrical contact. FIG. 29(c) shows the result of removing web 284b using a dry plasma etch, and sputter-coating the exposed surfaces with a titanium adhesion layer followed by a nickel layer 292 that functions as a seed layer for electroplating as well as a diffusion barrier. In FIG. 29(d) surface 293 has been polished to remove the Ti/Ni films, but they remain coating the walls and the bottom of well 291. Finally, in FIG. 29(e), well 291 has been filled with solder paste 294 using a squeegee. This completes special assembly layer 28. The preferred solder paste 294 is Indalloy 290 comprising 97% indium and 3% silver, melting at 143° C. A preferred well diameter is approximately 55 microns, and a preferred well depth is approximately 15 microns.

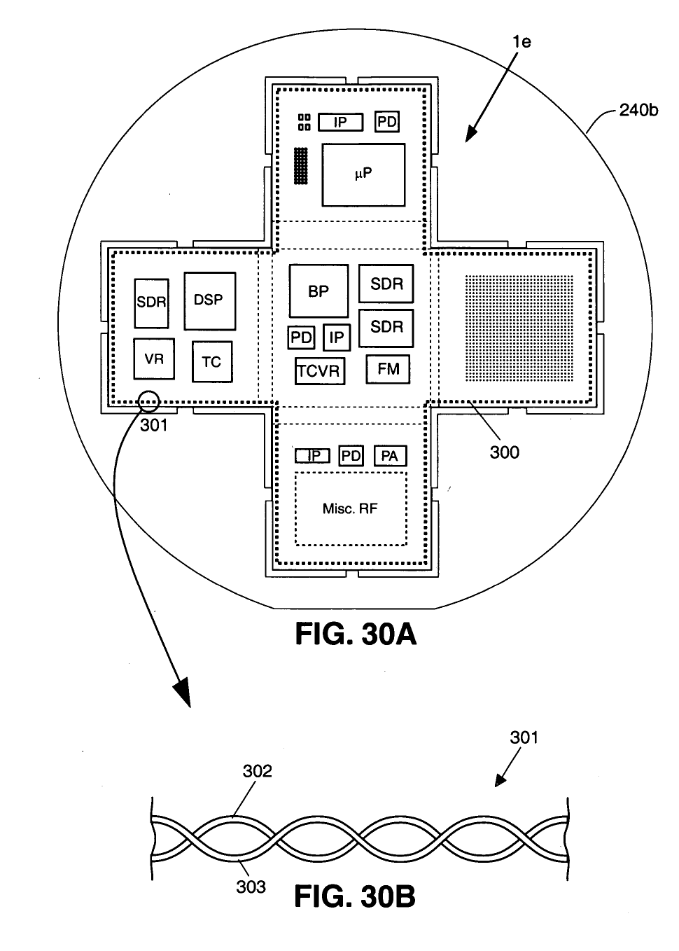

To date it has not been possible to imprint by hot embossing multiple layers in a stack wherein each of the layers includes the same or similar dielectric material with all of the layers softening at around the same temperature. Application of normal force 155 to imprint the current layer can compact or distort features in the previously imprinted layers. This application introduces two new methods to help solve this problem: the use of support rails neat the edge of each imprinted interconnection circuit, and selective heating of the dielectric stack. The support rails provide a limit stop 157 of FIG. 15 for the imprinting action, and the selective heating provides for heating and softening of only the topmost dielectric layer. FIG. 30A shows SIP assembly 1e on a copper wafer 240b. Near the edge of the interconnection circuit a dotted line path 300 shows the preferred location for a set of guard rails. A small region 301 of path 300 is expanded in FIG. 30B, which is a top X-ray view for revealing the vertical stack of metal features. Rail 302 is preferably shaped in the form of a sinusoid and is provided on each of the odd numbered layers in the stack. A similarly shaped rail 303 is offset as shown and provided on each of the even numbered layers in the stack. The rails are patterned at the same time as the trenches and vias; they are like elongated vias. Their width is preferably similar to the diameter of vias of the interconnection circuit. Their open structure allows good flow of the heated dielectric material during an imprint cycle. Even with some misalignment between layers their shape allows the rails on consecutive layers to interact appropriately, thereby providing a limit stop 157. The desired limit can be achieved either by measuring the imprinting stroke and stopping at a predetermined value, or by sensing the degree of resistance to the normal force 155 as the rail features of the embossing tool either touch or come into close proximity with the previously imprinted rails of the topmost layer.

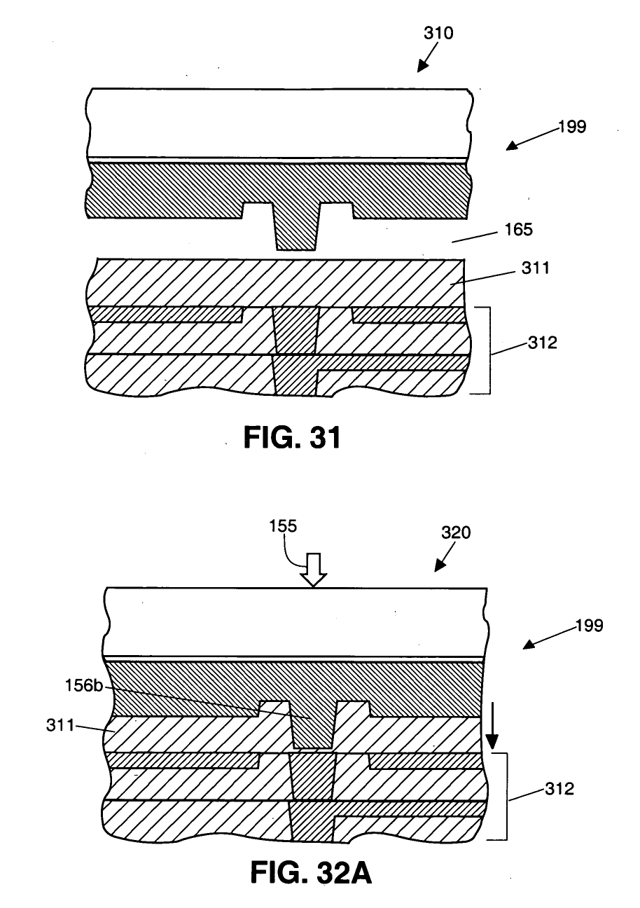

FIG. 31 illustrates an imprinting scenario 310 wherein embossing tool 199 of FIG. 19 is spaced apart from the topmost layer 311 of a stack that is about to be embossed. The medium 165 between them is preferably a vacuum, as previously discussed in reference to FIG. 16. It is desired that previously imprinted layers 312 shall not be affected by the imprinting of layer 311. In preparation for an imprinting action, embossing tool 199 is preferably raised to the embossing temperature, and the surface of layer 311 is thereby pre-heated and softened. An optimal embossing temperature can be determined from the flow properties (dynamic viscosity) of dielectric material 311 as a function of temperature, from the available range of normal force 155 of FIG. 15 in the embossing machine, and from the total area and depth of the features embossed. The preferred embossing temperature for Cytop is 220° C. in typical embossing scenarios. Preferably the imprint cycle follows a timed sequence. The depth of softening of layer 311 is dependent on the duration it is heated by embossing tool 199, so a consistent duration is desirable.

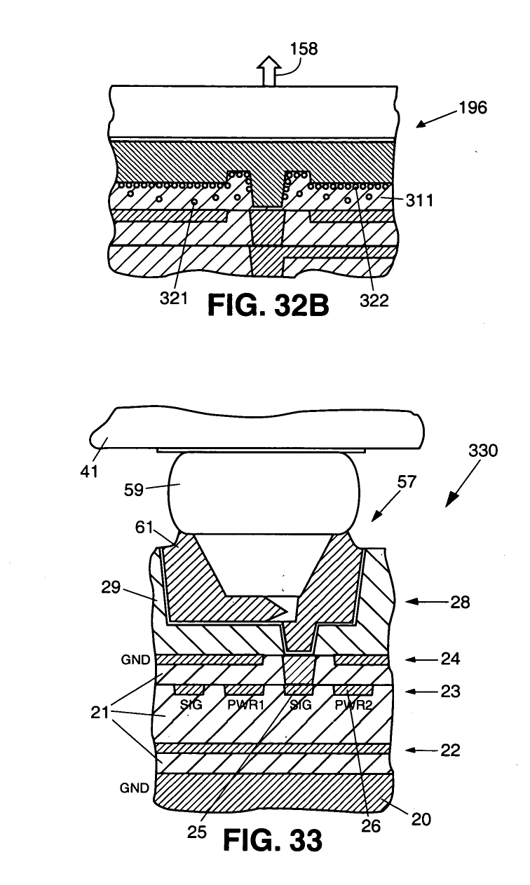

FIG. 32A illustrates a subsequent imprinting scenario 320 wherein the imprinting action occurs. Normal force 155 of FIG. 15 causes embossing tool 199 of FIG. 19 to penetrate topmost layer 311 as shown. Embossing features 156b are maintained at the desired embossing temperature as they imprint topmost layer 311 by using power resistor 204, temperature sensors 214 and 215, and a feedback control system such as is known in the art. The heated dielectric material of topmost layer 311 softens and flows to form the imprinted features. Preceding layers 312 do not soften significantly during this imprint cycle, and are not compacted by the normal force. This result requires that the embossing temperature and the duration of each step in the embossing cycle be well controlled. The steps may include pre-heat as in FIG. 31, and imprint as in FIG. 32A. In addition, guard rails 300 are preferably employed so that they (rather than any circuit structures) withstand the compressive forces, and provide a limit stop to the imprinting stroke, as previously described. Good temperature control is required for safety reasons as well. Cytop dielectric material 21 of FIG. 2 begins to decompose at 410° C. forming toxic compounds; it is recommended that it not be heated above 250° C.

FIG. 32B illustrates the physical phenomenon preferably used to create release force 158 of FIG. 15. This method of the current invention is called “vapor assisted release”. By precise timing and temperature control of the soft cure cycle of dielectric 21 of FIG. 2, a predetermined small amount of solvent or curing agent preferably remains in topmost dielectric layer 311 prior to the imprint cycle. Heat from embossing tool 199 of FIG. 19 at the embossing temperature causes molecules of gas 321 to form in layer 311 during the imprint cycle. Molecules 321 rise upward and coalesce to form a gaseous layer 322 at the interface between the stamp and the substrate. Gaseous layer 322 exerts an upward force 158 of FIG. 15 on embossing tool 199, thereby releasing the embossing features from the dielectric material being embossed. This automatic release of the stamp from the substrate is designed to eliminate the possibility of having to pry them apart, which could damage the parts, and which would also make the production cycle unpredictable and difficult to manage efficiently.

To account for thermal expansion of the imprinting tool its critical dimensions must be sized at the selected embossing temperature, including the spacing between alignment targets. Conversely, the critical dimensions of the substrate being imprinted are sized at a temperature close to room temperature, including the copper substrate and all of the layers except the topmost layer being imprinted.

It is also important that the lateral dimensions of the hot-embossed features do not change appreciably due to shrinkage as the materials cool after an imprint cycle. It should be anticipated that lateral shrinkage could occur as the topmost imprinted layer cools to match the temperature of the lower layers. However, the CMP process can be designed to leave a controlled amount of surface roughness at polished surfaces such as 287 of FIG. 28; this can be achieved by selection of the abrasive materials and other CMP operating parameters. This controlled surface roughness serves to anchor the subsequently deposited dielectric layer (preferably spun on), helping to prevent lateral motion at the interface. In addition, the (vertical) thickness of the topmost dielectric layer adjusts (shrinks) as the layer cools. This relieves stress and mitigates any lateral (horizontal) movement of the embossed features.

A fragment showing the preferred SIP structure 330 in cross-section is shown in FIG. 33. There are preferably four imprinted layers as shown, 22, 23, 24, and 28 as in FIG. 2. Substrate 20 is conductive, and is preferably copper or a copper alloy. Dielectric material 21 is preferably Cytop as previously discussed, or a similar imprintable material having a low dielectric constant and a low dissipation factor. Dielectric layer 29 is also imprintable, and does not soften at the preferred temperature for melting the solder of bump/well connections 57 of FIGS. 5 and 6 during assembly or rework; an unfilled epoxy or a polyimide such as BCB are suitable materials for this layer. The preferred type of bump is a gold stud bump 59 (FIG. 5), and the solder 61 (FIG. 6) filling the wells is preferably Indalloy 290, having a melting point of 143° C. Signal trace 25 and power trace 26 are of FIG. 2 shown.

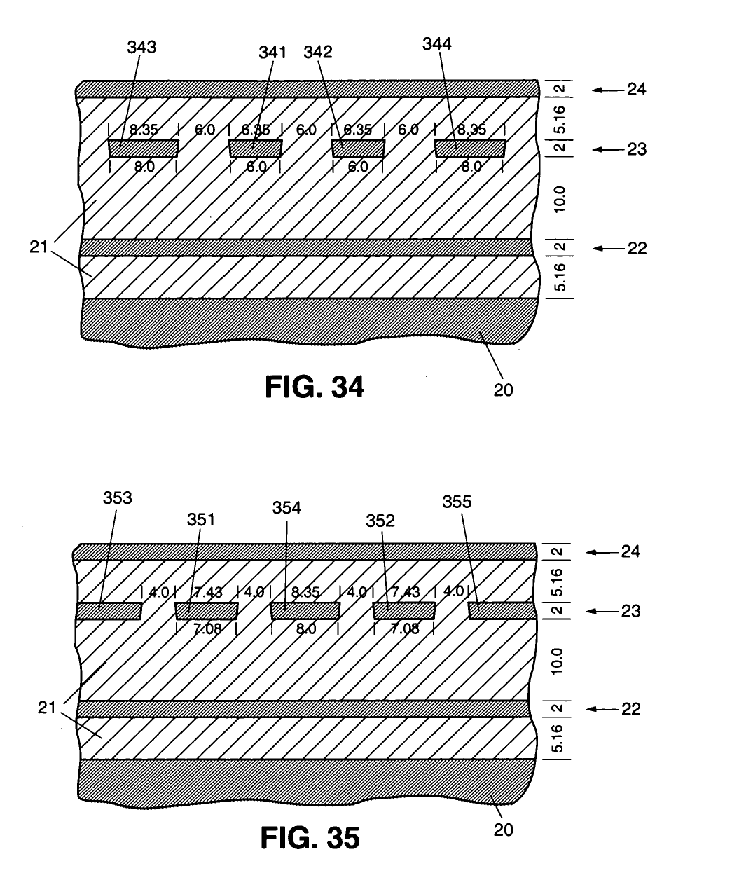

It is desirable for high frequency applications to fabricate signal traces like 25 as transmission lines so that they have a controlled impedance (also known as “characteristic impedance”). A power mesh architecture described by Happy Holden provides a way to fabricate an easily routed high-performance circuit having controlled impedance traces using four layers. An example is depicted in FIG. 34, with dimensions shown in microns. The dimensions given in FIGS. 34 and 35 are approximately 10-20 times smaller than typical dimensions fabricated using standard FR-4 circuit board materials. Instead of a typical minimum trace width of around 100 microns the current invention enables a trace width of around 5 microns. Similarly, a typical laminate thickness is 0.005 inches or 127 microns, compared with a preferred dielectric thickness of 5.2-10.0 microns for the current invention. This is significant because inductive loops can cause collapse of the power supply rails of the power distribution system (PDS), and the loop area can be reduced if the dielectric thickness between power conductors is reduced. The inductive loops associated with the conductive features shown in FIGS. 34 and 35 are also 10-20 times smaller than corresponding loops found in FR-4 laminate structures. Accordingly, devices of the current invention are expected to operate at frequencies 10-20 times higher. A typical characteristic impedance is 50 Ω for a single-ended trace and 100 Ω for a differential pair. A common acceptable tolerance on such characteristic impedances is ±10%, and this drives the required manufacturing precision. The imprinting methods described herein, coupled with typical CMP procedures, have the necessary precision to achieve the small feature sizes presented, as well as maintain a 10% manufacturing tolerance on the impedance. FIG. 34 illustrates a pair of traces 341 and 342 that are arranged as a differential pair having a preferred differential impedance of 100 Ω. Traces 341 and 342 are routed in between traces 343 and 344 that carry either GND or a DC voltage (PWR). Layer 24 of FIG. 2 is a GND plane in the preferred circuit structure, and carries some of the return current; traces 343 and 344 also carry a portion of the return current. Substrate 20 is preferably at GND potential. Layer 22 includes signal traces and power traces that are orthogonal to those of layer 23 in the preferred embodiment. This transmission line configuration is known as differential offset coplanar stripline.

FIG. 35 shows dimensions in microns for single ended traces 351 and 352 that have a preferred characteristic impedance of 50 Ω. They are routed between conductors 353, 354, and 355 that each carry either GND or PWR. Again, layer 22 of FIG. 2 carries orthogonal traces for signals and power; also layer 24 is a ground plane, and substrate 20 is preferably at GND. This transmission line configuration is known as offset coplanar stripline. Although the width of the traces and the spaces between them vary, the thickness of the copper layers and the dielectric layers in FIGS. 34 and 35 is the same; this means that single-ended and differential signals can be routed on the same layer.

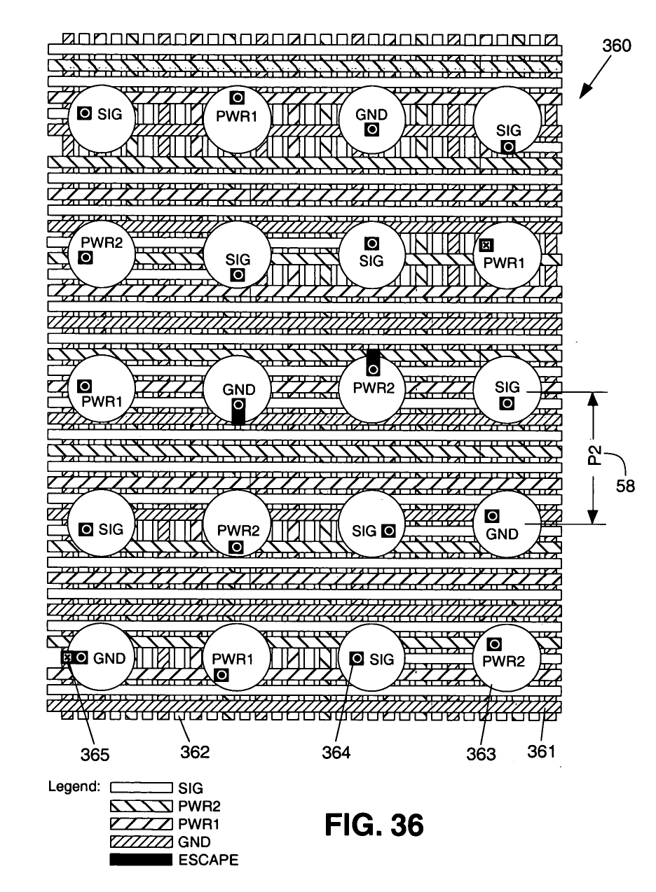

A known problem with conventional FR-4 boards is difficulty in routing the traces near the solder balls of a ball grid array, especially when a pitch of 1.0 mm or 0.8 mm is used (these pitches apply to a micro ball grid array). The special case of trace routing near a set of input/output terminals is known as “escape routing”. FIG. 36 shows escape routing 360 for the current invention, using the preferred 4-layer process, for an input/output pitch of 100μ or 0.1 mm (8 times closer spacing than the problematic case for epoxy laminate boards). The example is shown for a four-layer circuit with two power supply voltages, PWR1 and PWR2. Trace width and spacing are the same as shown in FIG. 35. Horizontal traces like 361 are on the upper level 23. Vertical traces like 362 are on the lower level 22 of FIG. 2. Circular areas 363 depict wells 60 of FIG. 6 as terminals to which stud-bumped devices can be attached. Contacts 364-to traces of the upper layer are shown as “O”s, and contacts 365 to traces of the lower layer are shown as “X”s. It can be seen that providing short escape traces to each well is not difficult; in this example only two contacts to lower level 22 are required. This is a demonstration of the routing density provided by the current invention compared with conventional epoxy-laminate boards.

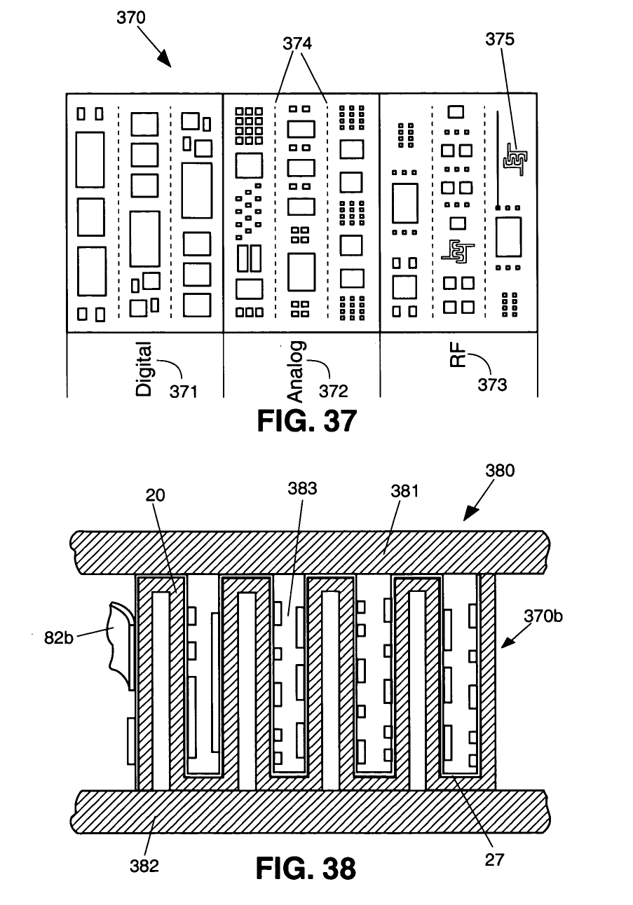

FIG. 37 shows an alternative substrate layout for a stacked package of the current invention, in the form of a strip assembly 370. Assembled microelectronic elements are preferably grouped by type: digital 371, analog 372, and RF 373. Chip-based elements are preferably arrayed in rows as shown, with a clear space between rows that can be used as a fold line 374. In this case, the “delineated surfaces” of the stacked package are defined by edges of the strip assembly 370 on 2 or 3 sides, and fold lines 374 on the remaining sides. The arrangement of the interconnection layers is preferably as shown in FIGS. 33-35. Some RF components may be created using shaped copper circuits on dielectric material 21 of FIG. 2; the combination of copper substrate 20, shaped copper circuit features such as coupler 375, and high performance dielectric 21 enable low-loss microwave and other RF circuits to be formed in this manner.

Strip assembly 370 is preferably folded to form folded assembly 370b shown in FIG. 38. Stacked assembly 380 preferably includes an upper copper plate 381 and a lower copper plate 382, provided for good thermal access to the heat generating components. Power and/or signals may be connected to assembly 380 using a cable such as cable 82b, as previously described in relation to FIG. 27B. Electrically shielded compartments 383 are created by this arrangement. The copper 20 of FIG. 2 surrounding each compartment 383 provides electrical isolation between compartments, like a Faraday cage. End plates (not shown) may be used to complete the cage. This shielding arrangement is useful for creating densely packaged systems with low levels of interference between compartments 383, as well as good cooling.

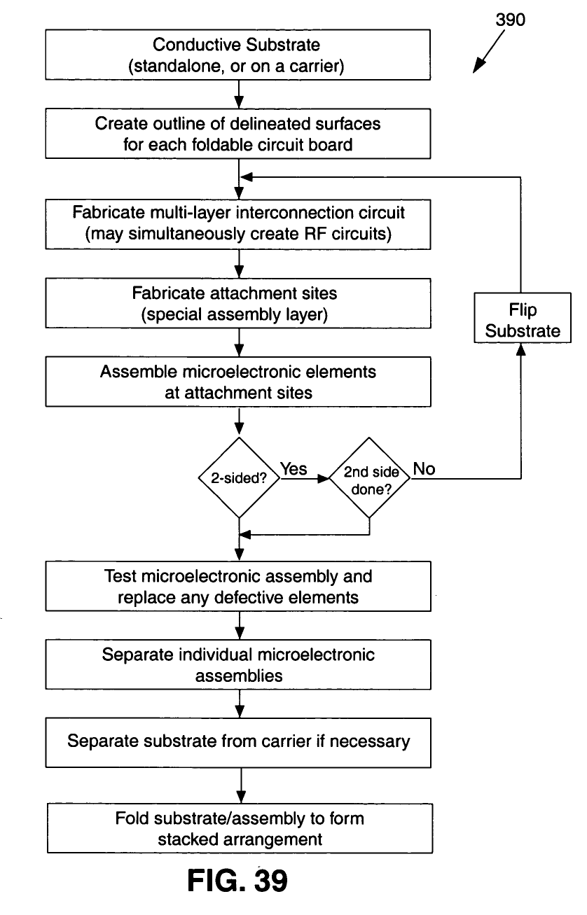

FIG. 39 depicts a flow chart 390 that summarizes the main features of a preferred process for building an SIP of the current invention.

1. A circuit board for a stacked package comprising:
an electrically conductive substrate having a plurality of foldable tabs or delineated surfaces; and,
a multi-layer interconnection circuit having conductive traces fabricated on one or both sides of said substrate, and one or more attachment sites on one or more of said tabs or delineated surfaces, said attachment sites having terminals for connection to selected traces in said interconnection circuit.

2. A circuit board comprising:
an electrically conductive substrate;
a multi-layer interconnection circuit having conductive traces fabricated on one or both sides of said substrate, and one or more attachment sites which include a plurality of attachment terminals with each of said terminals adapted to connect with selected traces of said interconnection circuit, wherein each of said terminals is either a bump or a well filled with solder.

3. The circuit board of claims 1 or 2 wherein said conductive substrate is copper or an alloy of copper.

4. The circuit board of claim 1 wherein each of said attachment terminals is either a conductive bump or a well filled with solder.

5. The circuit board of claims 2 or 4 wherein said solder is indium-based.

6. The circuit board of claims 1 or 2 wherein the minimum pitch of said attachment terminals is 100 microns or less.

7. The circuit board of claims 1 or 2 wherein said multi-layer interconnection circuit comprises interconnecting layers of copper conductors embedded in dielectric material.

8. The circuit board of claim 7 wherein said dielectric material includes Cytop.

9. The circuit board of claims 1 or 2 comprising:
an electrically conductive substrate which is copper or an alloy of copper;
a first dielectric layer;
a first patterned conductive layer including conductive power and signal traces;
a second dielectric layer;
a second patterned conductive layer including conductive power and signal traces;
a third dielectric layer;
a third patterned conductive layer in the form of a ground plane with feed-throughs for signals and power; and,
a fourth dielectric layer with terminals for attachment to selected traces formed therein.

10. The circuit board of claim 9 wherein some or all of said dielectric layers are Cytop.

11. The circuit board of claim 7 wherein selected ones of said copper conductors are arranged in said dielectric material to form transmission lines having controlled impedance.

12. The circuit board of claim 7 wherein selected ones of said copper conductors are shaped and arranged in said dielectric material to form RF circuits.

13. A high density cable comprising:
an electrically conductive substrate; a multi-layer interconnection circuit having conductive traces fabricated on said substrate and at least two attachment sites wherein each of said attachment sites includes a plurality of attachment terminals and each of said terminals connects with a selected trace of said interconnection circuit.

14. The cable of claim 13 wherein said attachment terminals are either gold stud bumps or wells filled with solder.

15. The cable of claim 13 wherein said multi-layer interconnection circuit comprises interconnecting layers of copper conductors embedded in dielectric material.

16. The cable of claim 15 wherein selected ones of said copper conductors are arranged in said dielectric material to form transmission lines having a characteristic impedance.

17. The cable of claim 13 wherein the pitch of said attachment terminals is 100 microns or less.

18. The cable of claims 13-17 and including multiple branches of said cable, wherein at least one of said attachment sites is provided in each of said branches.

19. A stacked microelectronic assembly comprising:
an electrically conductive substrate having a plurality of foldable tabs or delineated surfaces;
a multi-layer interconnection circuit having conductive traces fabricated on one or both sides of said conductive substrate and one or more attachment sites on one or more of said tabs or delineated surfaces, said attachment sites having terminals for connection to selected traces in said interconnection circuit;
a plurality of microelectronic elements attached at said attachment sites using said attachment terminals; and,
wherein at least one of said foldable tabs or delineated surfaces is folded to form a stacked arrangement of said folded tabs or delineated surfaces.

20. The stacked assembly of claim 19 wherein said electrically conductive substrate is copper or an alloy of copper.

21. The stacked assembly of claim 19 wherein each of said attachment terminals includes either a bump or a well.

22. The stacked assembly of claim 21 wherein said bump is a gold stud bump.

23. The stacked assembly of claim 21 wherein said well is filled with solder.

24. The stacked assembly of claim 23 wherein said solder is indium-based.

25. The stacked assembly of claim 19 wherein said plurality of microelectronic elements includes at least one integrated circuit chip.

26. The stacked assembly of claim 19 wherein said plurality of microelectronic elements includes at least one chip containing integrated passive devices.

27. The stacked assembly of claim 19 wherein said plurality of microelectronic elements includes at least one chip for regulating or distributing power.

28. The stacked assembly of claim 19 wherein said plurality of microelectronic elements includes at least one test chip.

29. The stacked assembly of claim 19 wherein said multi-layer interconnection circuit comprises interconnection layers of metal conductors embedded in dielectric material.

30. The stacked assembly of claim 29 wherein selected ones of said metal conductors are shaped to form RF circuits in or on said dielectric material.

31. The stacked assembly of claim 19 wherein each of said delineated surfaces is dedicated to microelectronic elements of a single type: digital, analog, or radio frequency.

32. The stacked assembly of claim 19 wherein at least one of said attachment sites is used for attaching a cable.

33. The stacked assembly of claim 19 wherein each of said microelectronic elements is replaceable, prior to folding of said tabs.

34. A method for fabricating a stacked microelectronic assembly comprising the steps of:
a) providing an electrically conductive substrate;
b) providing a plurality of delineated surfaces-in the plane of said conductive substrate;
c) fabricating a multi-layer interconnection circuit having conductive traces on said delineated surfaces;
d) providing one or more attachment sites on at least one of said delineated surfaces, each of said attachment sites including a plurality of attachment terminals, wherein each of said terminals may connect with a selected trace of said interconnection circuit;
e) attaching a plurality of microelectronic elements at said attachment sites using said attachment terminals;
f) providing a means to test said microelectronic elements by using a test chip at-one of said attachment sites, or by using a cable connecting between one of said attachment sites and an external tester;
g) testing said microelectronic assembly using said test means and replacing any of said microelectronic elements that prove defective;
h) dicing said conductive substrate to separate said microelectronic assemblies if more than one of said assemblies is provided on said conductive substrate; and,
i) folding one or more of said delineated surfaces to form a stack of said delineated surfaces, for each of said microelectronic assemblies.

35. A rugged microelectronic assembly comprising:
a base substrate of copper; an interconnection circuit fabricated on said base substrate;
one or more microelectronic assemblies attached to said interconnection circuit; and,
a top member of copper that is machined to accommodate any height variation in said assemblies.
